(19) United States
(12) Patent Application Publication
(10) Pub. No.: US 2015/0064840 A1
(43) Pub. Date: Mar. 5, 2015

(54) METHOD FOR FORMING OXIDE FILM, AND METHOD FOR MANUFACTURING SEMICONDUCTOR DEVICE

(71) Applicant: Semiconductor Energy Laboratory Co., Ltd., Atsugi-shi (JP)

(72) Inventors: Akihisa SHIMOMURA, Atsugi (JP); Masashi OOTA, Atsugi (JP); Yoshinori YAMADA, Atsugi (JP)

(21) Appl. No.: 14/464,932

(22) Filed: Aug. 21, 2014

(30) Foreign Application Priority Data
Aug. 27, 2013 (JP) 2013-176003

(51) Int. Cl. H01L 21/02

(52) U.S. Cl. CPC H01L 21/02609; H01L 21/02595; H01L 21/02565; H01L 21/02667
USPC 438/104

(57) ABSTRACT

A method for forming a single crystal oxide film with high productivity is provided. Further, a method for forming a single crystal oxide film at a lower temperature is provided. In addition, a method for forming a single crystal oxide film by a simpler method is provided. An oxide film having crystal parts is formed over a formation surface, and the oxide film is single crystallized by performing heat treatment. Further, an oxide film having crystal parts in which the c-axis are aligned in a direction parallel to a normal direction of the formation surface or a normal direction of a surface of the oxide film and having no crystal grain boundary between the crystal parts is used as the oxide film formed over the formation surface.

### BACKGROUND OF THE INVENTION

1. Field of the Invention

One embodiment of the present invention relates to an oxide film and a method for forming the oxide film. In particular, one embodiment of the present invention relates to a semiconductor film and a method for forming the semiconductor film.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a light-emitting device, a storage device, a method for driving any of them, and a method for manufacturing any of them.

In this specification and the like, a semiconductor device generally means a device that can function by utilizing semiconductor characteristics. A transistor, a semiconductor circuit, an arithmetic device, a memory device, an imaging device, an electro-optical device, a power generation device (including a thin film solar cell, an organic thin film solar cell, and the like), and an electronic appliance each may include a semiconductor device.

2. Description of the Related Art

As a semiconductor used for the semiconductor device, silicon-based semiconductor materials are widely known. In recent years, however, an oxide exhibiting semiconductor characteristics (hereinafter referred to an oxide semiconductor) has been attracting attention as a new semiconductor which replaces silicon.

In addition, it has been considered to form a single crystal oxide film. Patent Document 1 discloses that LuGaO₃(ZnO)₉ thin film is formed by a PLD method over a single crystal ZnO thin film which is formed over a YSZ substrate by epitaxial growth, and then heat treatment is performed at 1450° C. to form a single crystal film; and that an In₂O₃ thin film is formed by a PLD method, and heat treatment is performed at 1300° C. to form a single crystal film.

Further, Non—Patent Document 1 discloses that an InGaO₃(ZnO)₅ thin film is formed by a PLD method over a ZnO single crystal thin film which is formed over a YSZ substrate in a manner similar to that of Patent Document 1, and then heat treatment is performed at 1400° C. to obtain a single crystal film, and that a completely single crystal thin film cannot be obtained at a temperature lower than or equal to 1200° C. Moreover, according to Non—Patent Document 1, an InGaO₃(ZnO)₅ thin film is formed directly on a YSZ substrate without providing a single crystal ZnO thin film, and then heat treatment is performed to obtain a polycrystalline film having a clear grain boundary.

### REFERENCE

### Patent Document

[Patent Document 1] Japanese Published Patent Application No. 2003-137692

### Non-Patent Document

[Non-Patent Document 1] Kenji Nomura et al., J. Appl. Phys. Vol. 95, pp. 5532-5539 (2004)

### SUMMARY OF THE INVENTION

An object of one embodiment of the present invention is to provide a method for forming a single crystal oxide film with high productivity. Another object is to provide a method for forming a single crystal oxide film at a lower temperature. Another object is to provide a method for forming a single crystal oxide film by a simpler method. Another object is to provide an oxide film with high reliability. Another object is to provide a novel oxide film.

Another object of the present invention is to provide a highly reliable semiconductor device. Another object is to provide a novel semiconductor device.

Note that the descriptions of these objects do not preclude the existence of other objects. In one embodiment of the present invention, there is no need to achieve all the objects. Other objects will be apparent from and can be derived from the description of the specification, the drawings, the claims, and the like.

One embodiment of the present invention is a method for forming an oxide film, including: forming an oxide film comprising crystal parts over a surface on which the film is formed (hereinafter referred to as a formation surface); and performing single-crystallization of the oxide film by performing heat treatment at a temperature higher than or equal to 800° C. and lower than or equal to 1400° C. Prior to the single-crystallization step, the crystal parts comprised in the oxide film have c-axis aligned with a direction parallel to a normal direction of the formation surface or a normal direction of a surface of the oxide film, and the oxide film does not have a crystal grain boundary between the crystal parts.

Further, one embodiment of the present invention is a method for forming an oxide film, including: forming a zinc oxide film over a formation surface: forming an oxide film comprising crystal parts over the zinc oxide film; and performing single-crystallization of the oxide film by performing heat treatment at a temperature higher than or equal to 800° C. and lower than or equal to 1400° C. Prior to the single-crystallization step, the crystal parts comprised in the oxide film have c-axis aligned with a direction parallel to a normal direction of a surface of the zinc oxide film or a normal direction of a surface of the oxide film, and the oxide film does not have a crystal grain boundary between the crystal parts.

Further, the zinc oxide film is preferably formed over the formation surface by a sputtering method at a room temperature.

Further, the formation surface preferably has crystallinity.

Further, the heat treatment is preferably performed under an atmosphere containing oxygen.

Further, another embodiment of the present invention is a method for manufacturing a semiconductor device, including: forming an oxide film according to any of the above methods for forming an oxide film; forming a pair of electrodes in contact with the oxide film; forming a gate insulating layer over the oxide film; and forming a gate electrode over the oxide film.

Note that in this specification and the like, the expression “crystallization” designates giving a material crystallinity or improving crystallinity of a material. In addition, the expression “single crystallization” designates transformation of a material into a single crystal.

According to an embodiment of the present invention, a method for forming a single crystal oxide film with high productivity can be provided. In addition, a method for forming a single crystal oxide film at a lower temperature can also be provided. Moreover, a method for forming a single crystal oxide film by a simpler method can also be provided. Further, a highly reliable semiconductor device can also be provided.

### BRIEF DESCRIPTION OF THE DRAWINGS

FIGS. 1A to 1C illustrate a method for forming an oxide film of an embodiment.

FIGS. 2A to 2D illustrate a method for forming an oxide film of an embodiment.

FIGS. 3A to 3C illustrate a structural example of a semiconductor device of an embodiment.

FIGS. 4A to 4C each illustrate an example of a structure of a semiconductor device of an embodiment.

FIGS. 5A to 5C each illustrate a structural example of a semiconductor device of an embodiment.

FIGS. 6A to 6C illustrate structural examples of a semiconductor device of an embodiment.

FIGS. 7A and 7B illustrate structural examples of a semiconductor device of an embodiment.

FIGS. 8A to 8E illustrate an example of a method for manufacturing a semiconductor device of the embodiment.

FIGS. 9A and 9B are circuit diagrams of semiconductor devices of an embodiment.

FIGS. 10A and 10B illustrate a structural example of a memory device of one embodiment.

FIG. 11 illustrates a structural example of an RFID tag of one embodiment.

FIG. 12 illustrates a structural example of CPU of an embodiment.

FIG. 13 is a circuit diagram of a memory element of one embodiment.

FIGS. 14A to 14C illustrate a structural example and circuit diagrams of a display device of an embodiment.

FIGS. 15A to 15F each illustrate an electronic device according to one embodiment.

FIGS. 16A to 16F each illustrate an application example of an RFID of one embodiment.

FIG. 17 is XPS analysis results of an example.

FIGS. 18A to 18C show results of XRD measurement in one example.

FIGS. 19A to 19C are STEM images according to an example.

FIGS. 20A and 20B are STEM images according to an example.

FIGS. 21A and 21B are STEM images according to an example.

FIGS. 22A and 22B are STEM images according to an example.

FIGS. 23A and 23B are HAADF-STEM images according to an example.

FIGS. 24A1, 24A2, 24B1 and 24B2 are STEM images according to an example.

FIGS. 25A and 25B show results of XRD measurement in one example.

FIGS. 26A and 26B are STEM images according to an example.

FIGS. 27A and 27B are STEM images according to an example.

### DETAILED DESCRIPTION OF THE INVENTION

Embodiments will be described in detail with reference to drawings. Note that the present invention is not limited to the description below, and it is easily understood by those skilled in the art that various changes and modifications can be made without departing from the spirit and scope of the present invention. Accordingly, the present invention should not be interpreted as being limited to the content of the embodiments below.

Note that in the structures of the invention described below, the same portions or portions having similar functions are denoted by the same reference numerals in different drawings, and description of such portions is not repeated. Further, the same hatching pattern is applied to portions having similar functions, and the portions are not especially denoted by reference numerals in some cases.

Note that in each drawing described in this specification, the size, the layer thickness, or the region of each component is exaggerated for clarity in some cases. Therefore, embodiments of the present invention are not limited to such a scale.

Note that in this specification and the like, ordinal numbers such as “first”. “second”, and the like are used in order to avoid confusion among components and do not limit the number.

### Embodiment 1

In this embodiment, a method for forming an oxide film of one embodiment of the present invention will be described.

According to one embodiment of the present invention, an oxide film including crystal parts is formed over a formation surface, and heat treatment is performed on the oxide film, whereby the oxide film is single-crystallized (has undergone a single-crystallization). Further, in each of the crystal parts in the oxide film formed over the formation surface, the c-axis is aligned with a direction parallel to a normal direction of the formation surface or a normal direction of a surface of the oxide film; and there is no crystal grain boundary between the crystal parts in the oxide film. With the use of such an oxide film, a single crystal oxide film formed through heat treatment becomes a single crystal in which the c-axis is aligned with a direction parallel to a normal direction of the formation surface or a normal direction of the surface of the oxide film.

In addition, with the use of such an oxide film including crystal parts, a single crystal oxide film having good quality can be formed even when heat treatment is performed at a relatively low temperature. This is because the orientations of crystal parts in the oxide film before heat treatment are originally aligned; thus, high energy as energy required for rearrangement of atoms is not needed as compared with the case where an amorphous oxide film or a polycrystalline oxide film is used, for example.

Here, as an apparatus for performing heat treatment with high productivity, a vertical furnace using quartz and the like as interior materials such as a tube and a boat is known. However, at a temperature higher than 1300° C. as disclosed in Patent Document 1 and Non Patent Document 1, it becomes difficult to perform treatment in consideration of the heat resistance of these materials. In the case of using a furnace provided with such materials as interior materials, the furnace is preferably used at a temperature lower than or equal to 1300° C. and preferably lower than or equal to 1200° C. in terms of maintenance of the apparatus. Moreover, in the case where a furnace is used at a temperature which exceeds 1300° C., a muffle furnace provided with a ceramic partition wall needs to be used, for example, but such a furnace has problems in that the productivity cannot be increased since it is difficult to increase the size of the furnace; and contamination to a substrate to be processed is a concern since it is difficult to keep the furnace clean.

According to the method for forming an oxide film of one embodiment of the present invention, a sufficiently crystallized single crystal oxide film can be formed by performing heat treatment at a temperature of higher than or equal to 800° C. and lower than or equal to 1200° C., for example. On the other hand, while the time required for crystallization can be shortened as the processing temperature becomes higher, the temperature of the heat treatment is preferably lower than or equal to 1400° C., more preferably lower than or equal to 1200° C. since part of the oxide film is sublimed and reduction in the thickness of the oxide film becomes remarkable at a temperature which exceeds 1400° C., for example.

Therefore, the temperature of the heat treatment can be set to be higher than or equal to 800° C. and lower than or equal to 1400° C., preferably higher than or equal to 800° C. and lower than or equal to 1300° C., further preferably higher than or equal to 800° C. and lower than or equal to 1200° C., for example.

In addition, according to the method for forming an oxide film of one embodiment of the present invention, an oxide film including crystal parts having c-axis alignment can be formed over a formation surface regardless of the crystallinity of the formation surface. That is, a single crystal oxide film can be formed over the formation surface without using the ZnO film which is formed by epitaxial growth as disclosed in the Patent Document 1 and the Non—Patent Document 1.

In order to perform epitaxial growth of ZnO, deposition needs to be performed while a single crystal substrate is heated at a high temperature (e.g. at 600° C.). Therefore, a special apparatus is needed and the manufacturing process becomes complicated, which leads to a decrease in productivity. On the other hand, according to the method for forming an oxide film of one embodiment of the present invention, such a process is unnecessary; accordingly, productivity can be improved.

### [Formation Method 1]

A more specific example of a method for forming an oxide film is described below with reference to drawings.

### [Substrate]

First, a substrate 101 is prepared.

A material having resistance high enough to withstand at least heat in a later heating step is used as a substrate 101. For example, an yttria-stabilized zirconia (YSZ) substrate, a sapphire substrate, a quartz substrate, and a semiconductor substrate using silicon, silicon carbide, gallium nitride, gallium oxide, and or the like can be used.

In addition, a single crystal substrate is used as the substrate 101, and a substrate whose formation surface is a particular crystal plane is preferably used. Using a single crystal substrate as the substrate 101 enables a crystal part in an oxide film 112 formed later to have high orientation in an a-b plane direction, so that energy required for rearrangement of atoms in later heat treatment is reduced; accordingly, a favorable single crystal oxide film can be formed at a lower temperature.

### [Formation of Oxide Film]

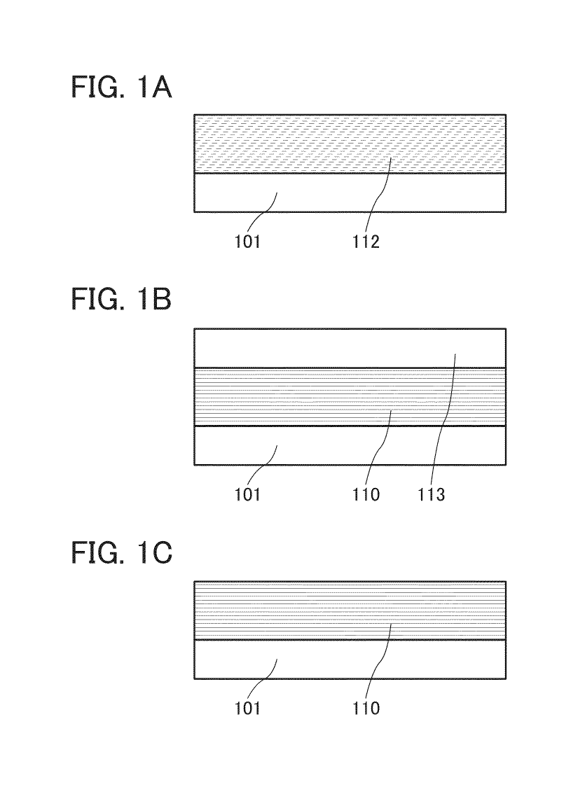

Then, the oxide film 112 is formed over the substrate 101 (see FIG. 1A).

First, the oxide film 112 to be formed is described.

An oxide semiconductor forming the oxide film 112 has a wide energy gap of 3.0 eV or more. A transistor including an oxide semiconductor film obtained by processing of the oxide semiconductor in an appropriate condition and a sufficient reduction in carrier density of the oxide semiconductor can have much lower leakage current between a source and a drain in an off state (off-state current) than a conventional transistor including silicon.

An applicable oxide semiconductor preferably contains at least indium (In) or zinc (Zn). In particular, In and Zn are preferably contained. In addition, as a stabilizer for reducing variation in electric characteristics of the transistor using the oxide semiconductor, one or more selected from gallium (Ga), tin (Sn), hafnium (Hf), zirconium (Zr), titanium (Ti), scandium (Sc), yttrium (Y), and an lanthanoid (such as cerium (Ce), neodymium (Nd), or gadolinium (Gd), for example) is preferably contained.

As the oxide semiconductor, for example, any of the following can be used: indium oxide, tin oxide, zinc oxide, an In—Zn-based oxide, a Sn—Zn-based oxide, an Al—Zn-based oxide, a Zn—Mg-based oxide, a Sn—Mg-based oxide, an In—Mg-based oxide, an In—Ga-based oxide, an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—Zr—Zn-based oxide, an In—Ti—Zn-based oxide, an In—Sc—Zn-based oxide, an In—Y—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an in—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide.

Here, an “In—Ga—Zn-based oxide” means an oxide containing In, Ga, and Zn as its main components and there is no particular limitation on the ratio of In, Ga, and Zn. The In—Ga—Z-based oxide may contain another metal element in addition to In, Ga, and Zn.

Alternatively, a material represented by InMO₃(ZnO)ₘ (m>0 is satisfied, and m is not an integer) may be used as an oxide semiconductor. Note that M represents one or more metal elements selected from Ga, Fe, Mn, and Co, or the above-described element as a stabilizer. Alternatively, as the oxide semiconductor, a material represented by a chemical formula, In₂SnO₅(ZnO) (n>0, n is a natural number) may be used.

For example, an In—Ga—Zn-based oxide with an atomic ratio of In:Ga:Zn=1:1:5, In:Ga:Zn=1:1:3, In:Ga:Zn=1:1:1, In:Ga:Zn=1:3:2, In:Ga:Zn=1:3:4, or In:Ga:Zn=1:3:6, In:Ga:Zn=3:1:2, In:Ga:Zn=2:1:3, or an oxide with an atomic ratio close to the above atomic ratios can be used.

In the case where the oxide film 112 is formed by a sputtering method, a target containing indium is preferably used in order to reduce the number of particles. In addition, if an oxide target having a high atomic ratio of the element M is used, the conductivity of the target may be decreased. Particularly in the case where a target containing indium is used, the conductivity of the target can be increased and DC discharge or AC discharge is facilitated; thus, deposition over a large substrate can be easily performed. Thus, semiconductor devices can be manufactured with improved productivity.

In the case where the oxide film 112 is formed by a sputtering method, the atomic ratio of In to M and Zn contained in the target may be 3:1:1, 3:1:2, 3:1:4, 2:2:1, 1:1:1, 1:1:2, 1:1:3, 1:1:4, 1:1:5, 4:2:4.1, 1:2:4, or the like.

In the case where the oxide film 112 is formed by a sputtering method, a film having an atomic ratio deviated from the atomic ratio of the target is formed in some cases. Especially for zinc, the atomic ratio of zinc in a deposited film is smaller than the atomic ratio of the target in some cases. Specifically, the film has an atomic ratio of zinc of 40 atomic % to 90 atomic % of the atomic ratio of zinc in the target.

Influence of impurities in the oxide film 112 is described below. In order to obtain stable electrical characteristics of a transistor, it is effective to reduce the concentration of impurities in the oxide film 112 to have lower carrier density so that the oxide film 112 is highly purified. The carrier density of the oxide film 112 is set to lower than 1×10¹⁷/cm³, lower than 1×10¹⁵/cm³, or lower than 1×10¹³/cm³. In order to reduce the concentration of impurities in the oxide film 112, the concentration of impurities in a film which is adjacent to the oxide film 112 is preferably reduced.

When hydrogen is contained in the oxide film 112, carrier density might be increased. Therefore, the concentration of hydrogen in the oxide film 112, which is measured by secondary ion mass spectrometry (SIMS), should be lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. When nitrogen is contained in the oxide film 112, the carrier density is increased in some cases. The concentration of nitrogen in the oxide film 112, which is measured by SIMS, can be set to be lower than 5×10¹⁹ atoms/cm³, preferably 5×10¹⁸ atoms/cm³ or lower, further preferably 1×10¹⁸ atoms/cm³ or lower, still further preferably 5×10¹⁷ atoms/cm³ or lower.

Further, the oxide film 112 is preferably a CAAC-OS (c-axis aligned crystalline oxide semiconductor) film. A CAAC-OS film will be described below.

In this specification, a term “parallel” indicates that the angle formed between two straight lines is greater than or equal to −10° and less than or equal to 10°, and accordingly also includes the case where the angle is greater than or equal to −5° and less than or equal to 5°. A term “perpendicular” indicates that the angle formed between two straight lines is greater than or equal to 80° and less than or equal to 100°, and accordingly also includes the case where the angle is greater than or equal to 85° and less than or equal to 95°.

In this specification, trigonal and rhombohedral crystal systems are included in a hexagonal crystal system.

The CAAC-OS film is one of oxide semiconductor films having a plurality of c-axis aligned crystal parts.

In a transmission electron microscope (TEM) image of the CAAC-OS film, a boundary between crystal pans, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflecting a surface over which the CAAC-OS film is formed (a formation surface) or a top surface of the CAAC-OS film, and is arranged parallel to the formation surface or the top surface of the CAAC-OS film.

On the other hand, according to the TEM image of the CAAC-OS film observed in a direction substantially perpendicular to the sample surface (plan-view TEM image), metal atoms are arranged in a triangular or hexagonal configuration in the crystal partns. However, there is no regularity of arrangement of metal atoms between different crystal parts.

From the results of the cross-sectional TEM image and the plan-view TEM image, alignment is found in the crystal parts in the CAAC-OS film.

Most of the crystal parts included in the CAAC-OS film each fit inside a cube whose one side is less than 100 nm. Thus, there is a case where a crystal part included in the CAAC-OS film fits inside a cube whose one side is less than 10 nm, less than 5 nm, or less than 3 nm. Note that when a plurality of crystal parts included in the CAAC-OS film are connected to each other, one large crystal region is formed in some cases. For example, a crystal region with an area of 2500 nm² or more, 5 μm² or more, or 1000 μm² or more is observed in some cases in the plan TEM image.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axis are aligned with a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor film of InGaZnO₄, six peaks appear. The six peaks are derived from crystal planes equivalent to the (110) plane. On the other hand, in the case of a CAAC-OS film, a peak is not clearly observed even when φ scan is performed with 2θ fixed at around 56°.

According to the above results, in the CAAC-OS film having c-axis alignment, while the directions of a-axis and b-axis are different between crystal parts, the c-axis are aligned with a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal parts are formed concurrently with deposition of the CAAC-OS film or are formed through crystallization treatment such as heat treatment. As described above, the c-axis of the crystal is aligned with a direction parallel to a normal vector of a formation surface or a normal vector of a top surface. Thus, for example, in the case where a shape of the CAAC-OS film is changed by etching or the like, the c-axis might not be necessarily parallel to a normal vector of a formation surface or a normal vector of a top surface of the CAAC-OS film.

Further, distribution of c-axis aligned crystal parts in the CAAC-OS film is not necessarily uniform. For example, in the case where crystal growth leading to the crystal parts of the CAAC-OS film occurs from the vicinity of the top surface of the film, the proportion of the c-axis aligned crystal parts in the vicinity of the top surface is higher than that in the vicinity of the formation surface in some cases. Further, when an impurity is added to the CAAC-OS film, a region to which the impurity is added is altered, and the proportion of the c-axis aligned crystal parts in the CAAC-OS film varies depending on regions, in some cases.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appear at around 31° and a peak of 2θ not appear at around 36°.

The CAAC-OS film is an oxide semiconductor film having low impurity concentration. The impurity is an element other than the main components of the oxide semiconductor film, such as hydrogen, carbon, silicon, or a transition metal element. In particular, an element that has higher bonding strength to oxygen than a metal element included in the oxide semiconductor film, such as silicon, disturbs the atomic arrangement of the oxide semiconductor film by depriving the oxide semiconductor film of oxygen and causes a decrease in crystallinity. Furthermore, a heavy metal such as iron or nickel, argon, carbon dioxide, or the like has a large atomic radius (molecular radius), and thus disturbs the atomic arrangement of the oxide semiconductor film and causes a decrease in crystallinity when it is contained in the oxide semiconductor film. Note that the impurity contained in the oxide semiconductor film might serve as a carrier trap or a carrier generation source.

The CAAC-OS film is an oxide semiconductor film having a low density of defect states. In some cases, oxygen vacancies in the oxide semiconductor film serve as carrier traps or serve as carrier generation sources when hydrogen is captured therein.

The state in which impurity concentration is low and density of defect states is low (the number of oxygen vacancies is small) is referred to as a “highly purified intrinsic” or “substantially highly purified intrinsic” state. A highly purified intrinsic or substantially highly purified intrinsic oxide semiconductor film has few carrier generation sources, and thus can have a low carrier density. Thus, a transistor including the oxide semiconductor film rarely has negative threshold voltage (is rarely normally on). The highly purified intrinsic or substantially highly purified intrinsic oxide semiconductor film has a low density of defect states, and thus has few carrier traps. Accordingly, the transistor including the oxide semiconductor film has little variation in electrical characteristics and high reliability. Electric charge trapped by the carrier traps in the oxide semiconductor film takes a long time to be released, and might behave like fixed electric charge. Thus, the transistor which includes the oxide semiconductor film having high impurity concentration and a high density of defect states has unstable electrical characteristics in some cases.

The CAAC-OS film is formed, for example, by the following method.

The CAAC-OS film is formed by a sputtering method using a polycrystalline oxide semiconductor sputtering target, for example. When ions collide with the sputtering target, a crystal region included in the sputtering target may be separated from the target along an a-b plane; in other words, a sputtered particle having a plane parallel to an a-b plane (flat-plate-like sputtered particle or pellet-like sputtered particle) may flake off from the sputtering target. In that case, the flat-plate-like sputtered particle or pellet-like sputtered particle reaches a substrate while maintaining its crystal state, whereby the CAAC-OS film can be formed.

The flat-plate-like or pellet-like sputtered particle has, for example, an equivalent circle diameter of a plane parallel to the a-b plane of greater than or equal to 3 nm and less than or equal to 10 nm, and a thickness (length in the direction perpendicular to the a-b plane) of greater than or equal to 0.7 nm and less than 1 nm. Note that in the flat-plate-like or pellet-like sputtered particle, the plane parallel to the a-b plane may be a regular triangle or a regular hexagon. Here, the term “equivalent circle diameter of a plane” refers to the diameter of a perfect circle having the same area as the plane.

For the deposition of the CAAC-OS film, the following conditions are preferably used.

By increasing the substrate temperature during the deposition, migration of sputtered particles is likely to occur after the sputtered particles reach a substrate surface. Specifically, the substrate temperature during the deposition is higher than or equal to 100° C. and lower than or equal to 740° C., preferably higher than or equal to 200° C. and lower than or equal to 500° C. By increasing the substrate temperature during the deposition, when the flat-plate-like or pellet-like sputtered particle reaches the substrate, migration occurs on the substrate surface, so that a flat plane of the sputtered particle is attached to the substrate. At this time, the sputtered particle is charged positively, whereby sputtered particles are attached to the substrate while repelling each other: thus, the sputtered particles do not overlap with each other randomly, and a CAAC-OS film with a uniform thickness can be deposited.

By reducing the amount of impurities entering the CAAC-OS layer during the deposition, the crystal state can be prevented from being broken by the impurities. For example, the concentration of impurities (e.g., hydrogen, water, carbon dioxide, or nitrogen) which exist in the deposition chamber may be reduced. Furthermore, the concentration of impurities in a deposition gas may be reduced. Specifically, a deposition gas whose dew point is −80° C. or lower, preferably −100° C. or lower is used.

Furthermore, it is preferable that the proportion of oxygen in the deposition gas be increased and the power be optimized in order to reduce plasma damage at the deposition. The proportion of oxygen in the deposition gas is higher than or equal to 30 vol %, preferably 100 vol %.

Alternatively, the CAAC-OS film is formed by the following method.

First, a first oxide semiconductor film is formed to a thickness of greater than or equal to 1 nm and less than 10 nm. The first oxide semiconductor film is formed by a sputtering method. Specifically, the substrate temperature is set to higher than or equal to 100° C. and lower than or equal to 500° C., preferably higher than or equal to 150° C. and lower than or equal to 450° C., and the proportion of oxygen in a deposition gas is set to higher than or equal to 30 vol %, preferably 100 vol %.

Next, heat treatment is performed so that the first oxide semiconductor film becomes a first CAAC-OS film with high crystallinity. The temperature of the heat treatment is higher than or equal to 350° C. and lower than or equal to 740° C. preferably higher than or equal to 450° C. and lower than or equal to 650° C. The heat treatment time is longer than or equal to 1 minute and shorter than or equal to 24 hours, preferably longer than or equal to 6 minutes and shorter than or equal to 4 hours. The heat treatment may be performed in an inert atmosphere or an oxidation atmosphere. It is preferable to perform heat treatment in an inert atmosphere and then perform heat treatment in an oxidation atmosphere. The heat treatment in an inert atmosphere can reduce the concentration of impurities in the first oxide semiconductor film for a short time. At the same time, the heat treatment in an inert atmosphere may generate oxygen vacancies in the first oxide semiconductor film. In such a case, the heat treatment in an oxidation atmosphere can reduce the oxygen vacancies. Note that the heat treatment may be performed under a reduced pressure, such as 1000 Pa or lower, 100 Pa or lower, 10 Pa or lower, or 1 Pa or lower. The heat treatment under the reduced pressure can reduce the concentration of impurities in the first oxide semiconductor film for a shorter time.

The first oxide semiconductor film can be crystallized easier in the case where the thickness is greater than or equal to 1 nm and less than 10 nm than in the case where the thickness is greater than or equal to 10 nm.

Next, a second oxide semiconductor film having the same composition as the first oxide semiconductor film is formed to a thickness of greater than or equal to 10 nm and less than or equal to 50 nm. The second oxide semiconductor film is formed by a sputtering method. Specifically, the substrate temperature is set to higher than or equal to 100° C. and lower than or equal to 500° C., preferably higher than or equal to 150° C. and lower than or equal to 450° C., and the proportion of oxygen in a deposition gas is set to higher than or equal to 30 vol %, preferably 100 vol %.

Next, heat treatment is performed so that solid phase growth of the second oxide semiconductor film is performed using the first CAAC-OS film, thereby forming a second CAAC-OS film with high crystallinity. The temperature of the heat treatment is higher than or equal to 350° C. and lower than or equal to 740° C., preferably higher than or equal to 450° C. and lower than or equal to 650° C. The heat treatment time is longer than or equal to 1 minute and shorter than or equal to 24 hours, preferably longer than or equal to 6 minutes and shorter than or equal to 4 hours. The heat treatment may be performed in an inert atmosphere or an oxidation atmosphere. It is preferable to perform heat treatment in an inert atmosphere and then perform heat treatment in an oxidation atmosphere. The heat treatment in an inert atmosphere can reduce the concentration of impurities in the second oxide semiconductor film for a short time. At the same time, the heat treatment in an inert atmosphere may generate oxygen vacancies in the second oxide semiconductor film. In such a case, the heat treatment in an oxidation atmosphere can reduce the oxygen vacancies. Note that the heat treatment may be performed under a reduced pressure, such as 1000 Pa or lower, 100 Pa or lower, 10 Pa or lower, or 1 Pa or lower. The heat treatment under the reduced pressure can reduce the concentration of impurities in the second oxide semiconductor film for a shorter time.

As described above, a CAAC-OS film with a total thickness of greater than or equal to 10 nm can be formed.

By the method described above, the oxide film 112 containing crystal parts whose c-axis are aligned with a direction parallel to a normal direction of a formation surface or a normal direction of a surface of the oxide film, and having no crystal grain boundary between the crystal parts is formed over the formation surface of the substrate 101.

The thickness of the oxide film 112 may be 1 nm to 500 nm, preferably 1 nm to 300 nm, for example. If the thickness of the oxide film 112 is too large, a region which is not completely crystallized might be formed depending on the conditions of heat treatment performed later.

Such an oxide film 112 can be formed even when the formation surface of the substrate 101 does not have crystallinity as described above. On the other hand, the formation surface of the substrate 101 preferably has crystallinity because the orientation of a crystal part in the a-b plane direction in the oxide film 112 is improved by being affected by atomic arrangement of the formation surface, whereby the conditions of later heat treatment can have high productivity.

### [Heat Treatment]

Next, the oxide film 112 is single-crystallized by performing heat treatment, whereby a single crystal oxide film 110 is formed (see FIG. 1B).

In order to suppress sublimation of part of an element in the oxide film 112, heat treatment is preferably performed in the state where a protective substrate 113 is provided in contact with the top surface of the oxide film 112 as illustrated in FIG. 1B.

The protective substrate 113 can be a substrate which is similar to that of the substrate 101.

Heat treatment may be performed in the state where a protective film is formed over the oxide film 112 instead of the protective substrate 113. The protective film can be formed by depositing a metal oxide film such as an aluminum oxide film or a tin oxide film by a sputtering method, a chemical vapor deposition (CVD) method, or the like.

The heat treatment is performed at a temperature higher than or equal to 800° C. and lower than or equal to 1400° C., preferably higher than or equal to 800° C. and lower than or equal to 1300° C., and more preferably higher than or equal to 800° C. and lower than or equal to 1200° C.

Here, the heat treatment is preferably performed under an atmosphere containing oxygen. By performing heat treatment in an atmosphere containing oxygen, a difference from the stoichiometric composition in the oxide film 112 due to the release of oxygen from the oxide film 112 is suppressed, whereby the single crystal oxide film 110 with good quality can be formed. The atmosphere of the heat treatment can be, for example, an air atmosphere, an oxygen atmosphere, and a mixed atmosphere containing inert gas such as a rare gas or nitrogen in addition to oxygen.

Atoms are rearranged by the heat treatment using a crystal part of the oxide film 112 as a nucleus, whereby the oxide film 112 is single-crystallized. Since crystal parts included in the oxide film 112 each have c-axis alignment as described above, energy required for rearrangement of atoms can be reduced and the heating temperature can be lowered as compared with the case where an amorphous film or a polycrystalline film is used.

After the heat treatment, the protective substrate 113 is removed (see FIG. 1C).

Thus, the single crystal oxide film 110 in which the c-axis is aligned with a direction parallel to the normal direction of the formation surface of the substrate 101 or the normal direction of the surface of the oxide film 112 can be formed over the substrate 101.

### [Formation Method 2]

An example of a method for forming a single crystal oxide film, which is partly different from the above-described Formation Method 1, is described with reference to drawings below. Note that description of the portions already described is omitted and only different portions are described in detail.

### [Formation of Buffer Film]

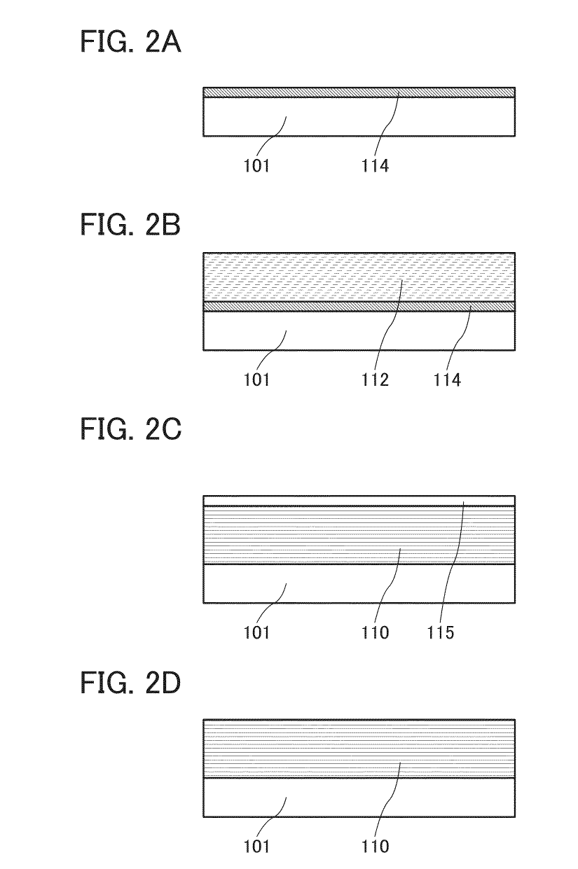

A buffer film 114 is formed over the substrate 101 (see FIG. 2A).

The buffer film 114 can reduce the lattice mismatch of the substrate 101 and the single crystal oxide film 110 to be formed later, and suppress generation of lattice defects such as dislocation in the single crystal oxide film 110. For the buffer film 114, a material whose lattice constant at the time of the material contained in the buffer film 114 is single-crystallized is close to that of the single crystal oxide film 110 is preferably used.

Further, for the buffer film 114, a material that is crystallized easily at a lower temperature than the material used for the oxide film 112 is preferably used. In later heat treatment, crystallization of the buffer film 114 proceeds earlier than the oxide film 112 and single crystal is formed, so that the orientations of the crystal parts in the oxide film 112 becomes easily aligned with each other in later rearrangement of atoms in the oxide film 112.

For example, when an In-M-Zn-based oxide is used as the oxide film 112, zinc oxide (ZnO) is preferably used as the buffer film 114.

Here, it is not necessary for the buffer film 114 to be a single crystal, and the buffer film 114 may be amorphous, microcrystalline or polycrystalline. Even when the buffer film 114 is amorphous, for example, the oxide film 112 including a crystal part having c-axis alignment can be formed thereover.

The buffer film 114 can be formed over the substrate 101, for example, by a sputtering method, an atomic layer deposition (ALD) method, an evaporation method, or the like at a room temperature. Therefore, an apparatus for forming the buffer film 114 does not need a special mechanism for heating the substrate 101; accordingly, the structure of the apparatus can be simpler. Moreover, the process time can be shortened because the time taken until the temperature of the substrate 101 stabilizes is not required.

The buffer film 114 may be formed thin enough to be uniformly attached to the surface of the substrate 101 or to cover the surface of the substrate 101. The thickness of the buffer film 114 is, for example, greater than or equal to 0.5 nm and less than or equal to 100 nm, preferably greater than or equal to 1 nm and less than or equal to 20 nm.

Note that the buffer film 114 may be deposited in the state where the substrate 101 is heated, whereby the buffer film 114 having crystallinity may be formed. When the atomic arrangement of the surface of the buffer film 114 which serves as the formation surface of the oxide film 112 to be formed later is aligned, orientation of crystal parts in the a-b plane direction in the oxide film 112 is improved; thus, the oxide film 112 can be crystallized at a lower temperature.

When a single crystal substrate is used as the substrate 101, the buffer film 114 which is crystallized by the heat treatment or the like in a later step tends to become a uniform single crystal; accordingly, the lattice mismatch with the single crystal oxide film 110 formed over the buffer film can be reduced effectively.

### [Formation of Oxide Film]

Subsequently, the oxide film 112 is formed over the buffer film 114 (see FIG. 2B). The oxide film 112 can be formed in a manner similar to that described in Formation Method 1.

Here, the buffer film 114 may be crystallized owing to heat applied during the formation of the oxide film 112.

### [Heat Treatment]

Next, heat treatment is performed on the oxide film 112 and the buffer film 114 (see FIG. 2C). The heat treatment can be performed in a manner similar to that described in Formation Method 1. FIG. 2C illustrates the case where the heat treatment is performed while a protective film 115 is provided over the oxide film 112.

Even in the case where the buffer film 114 is not a single crystal, rearrangement of atoms in the buffer film 114 having a relatively low melting point easily occurs in the initial stage of the heat treatment; thus, the buffer film 114 is crystallized earlier than the oxide film 112. Therefore, atoms in the oxide film 112 are rearranged based on the orientation of the crystal of the surface of the buffer film 114; accordingly, each crystals of the buffer film 114 and the single crystal oxide film 110 are aligned. In the case where a single crystal substrate is used as the substrate 101, the orientation of the crystal of the buffer film 114 is aligned with that of the crystal of the single crystal substrate; accordingly, the orientation of the crystal of the single crystal oxide film 110 is aligned with that of the crystal of the substrate 101.

In the case where a metal oxide including metal elements which are contained in the oxide film 112 is used as the buffer film 114, the buffer film 114 is taken into the oxide film 112 as the heat treatment proceeds as illustrated in FIG. 2C, which makes the boundary between the oxide film 112 and the buffer film 114 unclear. In some cases, the buffer film 114 remains between the substrate 101 and the single crystal oxide film 110 depending on the heating condition and the thickness of the buffer film 114.

By both providing the such a buffer film 114 and using the oxide film 112 including a crystal part having c-axis alignment, energy required for rearrangement of atoms in the oxide film 112 at the time of heat treatment is reduced; whereby the single crystal oxide film 110 with high crystallinity can be formed at a lower temperature. For example, even when the temperature is higher than or equal to 800° C. and lower than or equal to 1200° C. or higher than or equal to 800° C. and lower than or equal to 1000° C. the single crystal oxide film 110 with uniform and favorable crystallinity can be formed.

After the heat treatment, the protective film 115 is removed (see FIG. 2D). The protective film 115 is removed by wet etching, dry etching, or the like, for example.

Thus, the single crystal oxide film 110 in which the c-axis is aligned with a direction parallel to the normal direction of the formation surface of the substrate 101 or the normal direction of the surface of the oxide film 112 can be formed over the substrate 101.

At least part of this embodiment can be implemented in combination with any of the embodiments described in this specification as appropriate.

### Embodiment 2

In this embodiment, a structure example of a semiconductor device in one embodiment of the present invention and an example of a manufacturing method thereof will be described. A transistor is described below as an example of the semiconductor device. Note that portions similar to those described in Embodiment 1 are not described in some cases. When components have the same functions and properties as those described above, the same reference numerals are used and detailed description thereof is omitted in some cases.

### Structure Example

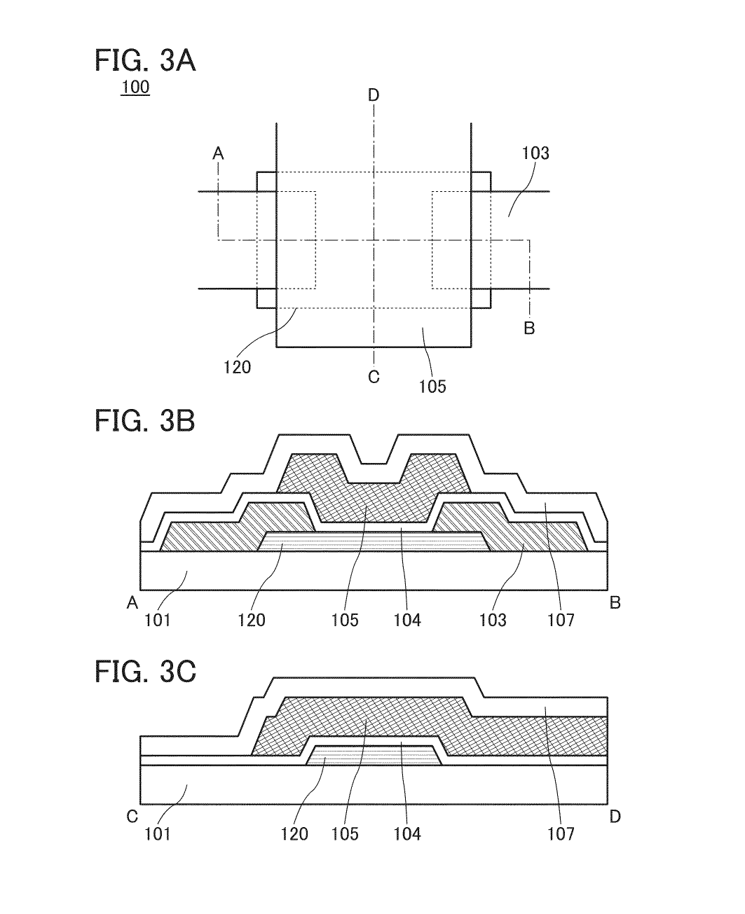

FIG. 3A is a schematic top view of a transistor 100 described in this structural example. FIG. 3B is a schematic cross-sectional view taken along line A-B in FIG. 3A, and FIG. 3C is a schematic cross-sectional view taken along line C-D in FIG. 3A. Note that some components are not illustrated in FIG. 3A for clarification.

The transistor 100 is provided over a substrate 101 and includes an island-shaped semiconductor layer 120, a pair of electrodes 103 in contact with a top surface of the semiconductor layer 120 and apart from each other in a region overlapping with the semiconductor layer 120, a gate electrode 105 formed over the semiconductor layer 120, and an insulating layer 104 provided between the semiconductor layer 120 and the gate electrode 105. In addition, an insulating layer 107 is provided so as to cover the above-described structure.

The semiconductor layer 120 includes the single crystal oxide film 110 described in Embodiment 1. Thus, since the transistor 100 has a single crystal oxide with favorable crystallinity in the semiconductor layer 120 in which a channel is formed, variation in characteristics of the transistor 100 can be reduced as compared to that of a transistor using polycrystalline having crystal grain boundaries, for example, and the variation in electrical characteristics of the transistor 100 can also be suppressed effectively. Therefore, the transistor 100 is a transistor with extremely high reliability.

Embodiment 1 can be referred to for materials and the like that can be used for the semiconductor layer 120.

One of the pair of electrodes 103 serves as a source electrode and the other serves as a drain electrode.

The insulating layer 104 serves as a gate insulating layer of the transistor 100.

The insulating layer 104 preferably includes a film from which oxygen is released by heating. For example, an insulating film including an oxygen-excess region is included. As the insulating film including the oxygen-excess region, an oxide insulating film containing oxygen in excess of the stoichiometric composition is preferably used, for example. Part of oxygen is released from such an oxide insulating film by heating.

With use of a film from which oxygen is released by heating as the insulating layer 104, oxygen is supplied from the insulating layer 104 to the semiconductor layer 120 by heat in the manufacturing process, which makes it possible to reduce oxygen vacancies in the semiconductor layer 120.

For the insulating layer 107, a material relatively impermeable to oxygen can be used. Furthermore, it is preferable that the insulating layer 107 be relatively impermeable to hydrogen or water. With the use of such a material for the insulating layer 107, it is possible to inhibit both diffusion of oxygen released from the insulating layer 104 to the outside and entry of hydrogen, water, or the like from the outside into the semiconductor layer 120 or the like.

### [Components]

Components of the transistor 100 are described below.

### [Semiconductor Layer]

In the case of using an oxide semiconductor as the semiconductor layer 120, an oxide semiconductor containing at least one of indium and zinc is preferably used. Typically, an In—Ga—Zn-based metal oxide can be given. An oxide semiconductor having a wider band gap and a lower carrier density than silicon is preferably used because off-state leakage current can be reduced.

### [Gate Electrode]

The gate electrode 105 can be formed using, for example, a metal selected from aluminum, chromium, copper, tantalum, titanium, molybdenum, and tungsten; an alloy containing any of these metals as a component; an alloy containing any of these metals in combination; or the like. Further, one or more metals selected from manganese and zirconium may be used. Alternatively, a semiconductor typified by polycrystalline silicon doped with an impurity element such as phosphorus, or a silicide such as nickel silicide may be used for the gate electrode 105. Furthermore, the gate electrode 105 may have a single-layer structure or a stacked-layer structure of two or more layers. For example, a single-layer structure of an aluminum film containing silicon, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, and the like can be given. Alternatively, an alloy film, or a nitride film containing aluminum and one or more metals selected from titanium, tantalum, tungsten, molybdenum, chromium, neodymium, and scandium may be used.

The gate electrode 105 can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a stacked-layer structure formed using the above light-transmitting conductive material and the above metal.

Further, an In—Ga—Zn-based oxynitride semiconductor film, an In—Sn-based oxynitride semiconductor film, an In—Ga-based oxynitride semiconductor film, an In—Zn-based oxynitride semiconductor film, a Sn-based oxynitride semiconductor film, an In-based oxynitride semiconductor film, a film of metal nitride (such as InN or ZnN), or the like may be provided between the gate electrode 105 and the insulating layer 104. These films each have a work function of 5 eV or higher, preferably 5.5 eV or higher, which is higher than the electron affinity of an oxide semiconductor; thus, the threshold voltage of a transistor including the oxide semiconductor can be shifted in the positive direction. Accordingly, a switching element having what is called normally-off characteristics is obtained. For example, as an In—Ga—Zn-based oxynitride semiconductor film, an In—Ga—Zn-based oxynitride semiconductor film having a higher nitrogen concentration than at least the semiconductor layer 102, specifically an In—Ga—Zn-based oxynitride semiconductor film having a nitrogen concentration higher than or equal to 7 at. %, is used.

### [Gate Insulating Layer]

The insulating layer 104 may be formed to have a single-layer structure or a stacked-layer structure using, for example, one or more of silicon oxide, silicon oxynitride, silicon nitride oxide, aluminum oxide, hafnium oxide, gallium oxide, Ga—Zn-based metal oxide, silicon nitride, and the like.

Alternatively, the insulating layer 104 may be formed using a high-k material such as hafnium silicate (HfSiOₓ), hafnium silicate to which nitrogen is added (HfSiₓO_{y}N_{z}), hafnium aluminate to which nitrogen is added (HfAlₓO_{y}N_{z}), or yttrium oxide.

As the insulating layer 104, an oxide insulating film containing oxygen in excess of the stoichiometric composition is preferably used. Part of oxygen is released by heating from the oxide insulating film containing oxygen in excess of the stoichiometric composition. The oxide insulating film containing oxygen in excess of the stoichiometric composition is an oxide insulating film in which the amount of released oxygen converted into oxygen atoms is greater than or equal to 1.0×10¹⁸ atoms/cm³, preferably greater than or equal to 3.0×10²⁰ atoms/cm³ in thermal desorption spectroscopy (TDS) analysis. Note that the substrate temperature in the TDS analysis is preferably higher than or equal to 100° C. and lower than or equal to 700° C., or higher than or equal to 100° C. and lower than or equal to 500° C.

When the specific material is used for the gate insulating layer, electrons are trapped in the gate insulating layer under specific conditions and the threshold voltage can be increased. For example, like a stacked-layer film of silicon oxide and hafnium oxide, part of the gate insulating layer uses a material having a lot of electron trap states, such as hafnium oxide, aluminum oxide, and tantalum oxide, and the state where the potential of the gate electrode is higher than that of the source electrode or the drain electrode is kept for one second or more, typically one minute or more at a higher temperature (a temperature higher than the operating temperature or the storage temperature of the semiconductor device, or a temperature of 125° C. or higher and 450° C. or lower, typically a temperature of 150° C. or higher and 300° C. or lower). Thus, electrons are moved from the semiconductor layer to the gate electrode, and some of the electrons are trapped by the electron trap states.

In the transistor in which a necessary amount of electrons is trapped by the electron trap states in this manner, the threshold voltage is shifted in the positive direction. By controlling the voltage of the gate electrode, the amount of electrons to be trapped can be controlled, and thus the threshold voltage can be controlled. Furthermore, the treatment for trapping the electrons may be performed in the manufacturing process of the transistor.

For example, the treatment is preferably performed at any step before factory shipment, such as after the formation of a wire metal connected to the source electrode or the drain electrode of the transistor, after the preceding process (wafer processing), after a wafer-dicing step, after packaging, or the like. In any case, it is preferable that the transistor be not exposed to a temperature higher than or equal to 125° C. for one hour or more after that.

### [Pair of Electrodes]

The electrodes 103 serving as source and drain electrodes are formed to have a single-layer structure or a stacked-layer structure using any of metals such as aluminum, titanium, chromium, nickel, copper, yttrium, zirconium, molybdenum, silver, tantalum, and tungsten, or an alloy containing any of these metals as its main component. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which a titanium film or a titanium nitride film, an aluminum film or a copper film, and a titanium film or a titanium nitride film are stacked in this order, a three-layer structure in which a molybdenum film or a molybdenum nitride film, an aluminum film or a copper film, and a molybdenum film or a molybdenum nitride film are stacked in this order, and the like can be given. Note that a transparent conductive material containing indium oxide, tin oxide, or zinc oxide may be used.

### [Insulating Layer]

As the material relatively impermeable to oxygen, which can be used for the insulating layer 107, for example, an insulating material such as silicon nitride, silicon nitride oxide, aluminum oxide, aluminum oxynitride, gallium oxide, gallium oxynitride, yttrium oxide, yttrium oxynitride, hafnium oxide, or hafnium oxynitride can be used. In particular, a material impermeable to oxygen, hydrogen, and water can be used.

The above is the description of each of the components.

### Modification Example 1

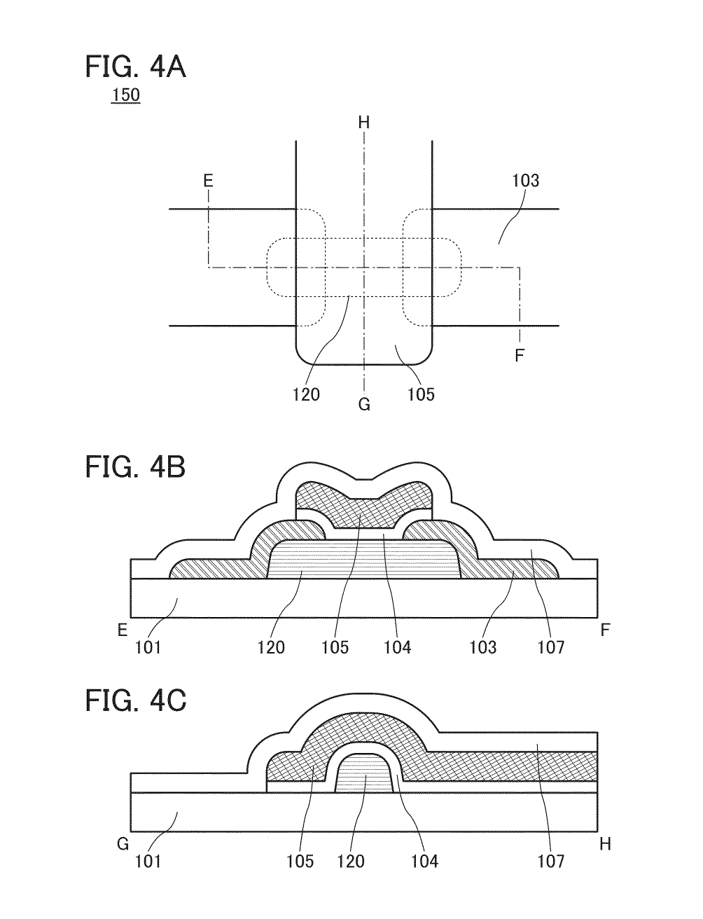

FIGS. 4A to 4C show a transistor 150 which has a structure suitable for miniaturization.

As illustrated in the cross-sectional view in the channel width direction in FIG. 4C, the corner portions of the semiconductor layer 120 from its side surface to its top surface are rounded in the transistor 150. Furthermore, the gate electrode 105 faces the top surface and side surfaces of the semiconductor layer 120. With such a structure, a channel is formed not only in the vicinity of the top surface but also in the vicinity of the side surfaces of the semiconductor layer 120, and an effective channel width is increased, resulting in an increase of current in the on state (the current is also referred to on-state current). In particular, in the case where the width of the semiconductor layer 120 is extremely small (for example, less than or equal to 50 nm, preferably less than or equal to 30 nm, more preferably less than or equal to 20 nm), a region where the channel is formed spreads inside the semiconductor layer 120, so that the on-state current is increased as the transistor is miniaturized.

Further, an example of the transistor 150 is illustrated in which the insulating layer 104 and the gate electrode 105 are processed with the use of one photomask so that the shapes of the insulating layer 104 and the gate electrode 105 are substantially aligned with each other when seen from above.

Note that in this specification and the like, the expression “shapes substantially aligned with each other when seen from above” means that at least outlines of stacked layers partly overlap with each other. For example, the case of patterning or partly patterning an upper layer and a lower layer with the use of the same mask pattern is included in the expression. The expression “shapes substantially aligned with each other when seen from above” includes the case where the outlines do not completely overlap with each other; for example, an end portion of an upper layer may be positioned on an inner side than an end portion of a lower layer, or may be positioned on an outer side than the end portion of the lower layer.

### Modification Example 2

A semiconductor device of one embodiment of the present invention preferably includes an oxide layer, which contains as its component at least one of the metal elements constituting an oxide semiconductor layer, between the oxide semiconductor layer and an insulating layer that overlaps with the oxide semiconductor layer. In this way, a trap state is prevented from being formed in the interface between the oxide semiconductor layer and the insulating layer that overlaps with the oxide semiconductor layer.

That is, one embodiment of the present invention preferably has a structure in which at least a top surface, a bottom surface, or both of them in a channel formation region are in contact with an oxide layer serving as a barrier film that prevents formation of an interface state at an interface with the oxide semiconductor layer. With this structure, formation of oxygen vacancies and entry of impurities which cause generation of carriers in the oxide semiconductor layer and the interface can be prevented. Thus, a highly purified intrinsic oxide semiconductor layer can be obtained. Obtaining a highly purified intrinsic oxide semiconductor layer refers to purifying or substantially purifying the oxide semiconductor layer to be an intrinsic or substantially intrinsic oxide semiconductor layer. It is thus possible to reduce variation in the electrical characteristics of a transistor including the oxide semiconductor layer and to provide a highly reliable semiconductor device.

Note that in this specification and the like, in the case of the substantially purified oxide semiconductor layer, the carrier density thereof is lower than 1×10¹⁷/cm³, lower than 1×10¹⁵/cm³, or lower than 1×10¹³/cm³. With a highly purified intrinsic oxide semiconductor layer, the transistor can have stable electric characteristics.

More specifically, the following structures can be employed for example.

### Modification Example 2-1

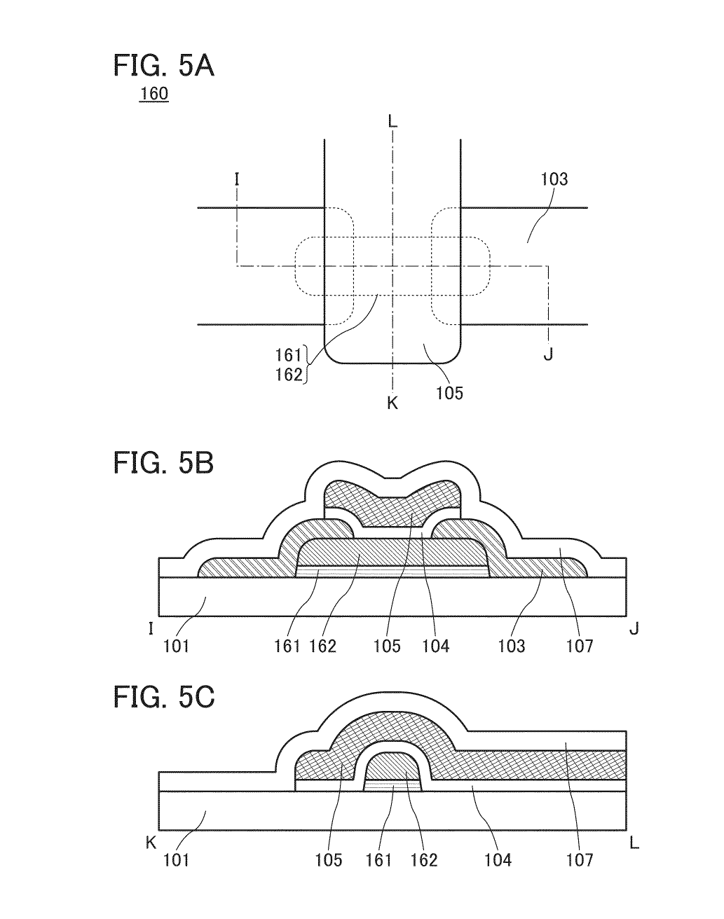

A transistor 160 illustrated in FIGS. 5A to 5C includes an oxide layer 161 and a semiconductor layer 162 instead of a semiconductor layer 120 as in the transistor 150 illustrated in FIGS. 4A to 4C.

The single crystal oxide film 110 described in the above embodiment can be used for the oxide layer 161. The oxide film 112 described in the above embodiment can be used for the semiconductor layer 162.

Here, the oxide layer 161 is an oxide containing at least one of metal elements included in the semiconductor layer 162. Further, for example, the oxide layer 161 contains In or Ga; typically, a material such as an In—Ga-based oxide, an In—Zn-based oxide, or an In-M-Zn-based oxide (M is Al, Ti, Ga, Y, Zr, La, Ce, Nd, or Hf) that has an energy level of the conduction band minimum closer to the vacuum level than that of the semiconductor layer 162 is used. Typically, the difference between the energy of the conduction band minimum of the oxide layer 161 and the energy of the conduction band minimum of the semiconductor layer 162 is preferably 0.05 eV or higher, 0.07 eV or higher, 0.1 eV or higher, or 0.15 eV or higher and 2 eV or lower, 1 eV or lower, 0.5 eV or lower, or 0.4 eV or lower.

For example, in the case where an In-M-Zn oxide is used for the oxide layer, as the proportion of In to M in the film becomes higher, the energy at the conduction band minimum can be further reduced. As the proportion of Zn becomes higher, the stability of the crystal structure can be increased. As the proportion of M becomes higher, release of oxygen from the oxide can be suppressed.

By providing the oxide layer 161 and the semiconductor layer 162 as described above, a channel is mainly formed in the semiconductor layer 162. Consequently, the formation of trap states at the interface on the substrate 101 side of the semiconductor layer 162 in which the channel is formed is suppressed; thus, it is possible to reduce variation in the electrical characteristics of the transistor 160, which enables a high reliable semiconductor device.

### Modification Example 2-2

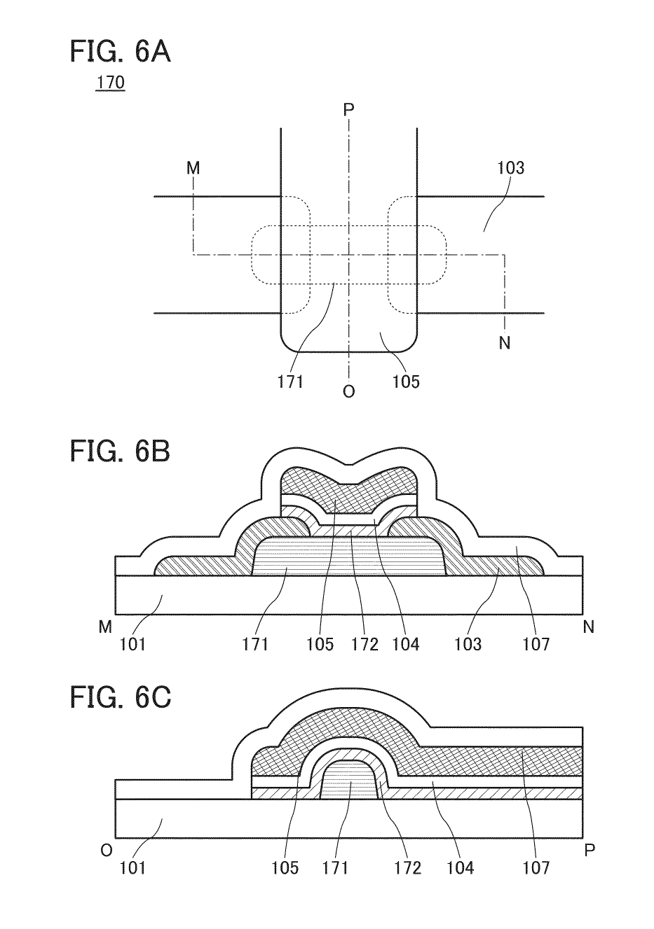

A transistor 170 illustrated in FIGS. 6A to 6C includes a semiconductor layer 171 instead of the semiconductor layer 120 as in the transistor 150 illustrated in FIGS. 4A to 4C, and further includes an oxide layer 172 between the semiconductor layer 171 and the insulating layer 104.

The single crystal oxide film 110 described in the above embodiment can be used for the semiconductor layer 171. The oxide film 112 described in the above embodiment can be used for the oxide layer 172.

Further, the oxide layer 172 is preferably formed using a material similar to that of the oxide layer 161 in the above structure example.

By providing the semiconductor layer 171 and the oxide layer 172 as described above, a channel is mainly formed in the semiconductor layer 171. Consequently, the formation of trap states at the interface on the insulating layer 104 side of the semiconductor layer 171 in which the channel is formed is suppressed; thus, it is possible to reduce variation in the electrical characteristics of the transistor 170, which enables a high reliable semiconductor device.

### Modification Example 2-3

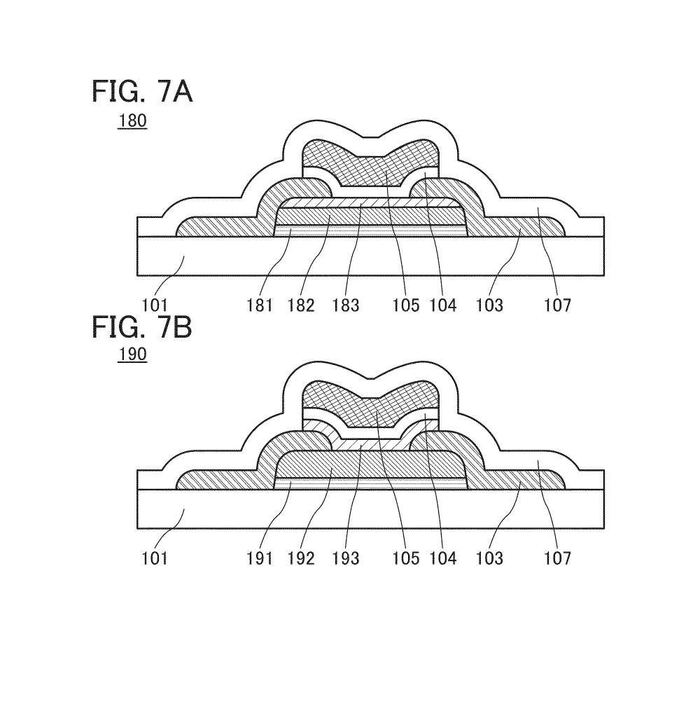

A transistor 180 illustrated in FIG. 7A includes an oxide layer 181, a semiconductor layer 182, and an oxide layer 183 instead of the semiconductor layer 120 as in the transistor 150 illustrated in FIGS. 4A to 4C.

The single crystal oxide film 110 described in the above embodiment can be used for the oxide layer 181. Further, the oxide film 112 described in the above embodiment can be used for the semiconductor layer 182 and the oxide layer 183.

In addition, the oxide layers 181 and 183 are preferably formed using a material similar to that of the oxide layer 161 in the above structure example. For the oxide layers 181 and 183, materials with the same composition or material with different compositions may be used.

By using a material in which the energy level of the conduction band minimum is closer to the vacuum level than that of the semiconductor layer 182 is used for the oxide layers 181 and 183, a channel is mainly formed in the semiconductor layer 182, so that the semiconductor layer 182 serves as a main current path. When the semiconductor layer 182 in which the channel is formed is sandwiched between the oxide layers 181 and 183 containing the same metal element as described above, formation of interface states between these films is suppressed, and thus reliability of the electrical characteristics of the transistor is improved. That is, the formation of trap states at the interfaces on the insulating layer 104 side and on the substrate 101 side of the semiconductor layer 182 in which the channel is formed is suppressed; thus, it is possible to reduce variation in the electrical characteristics of the transistor 180, which enables a high reliable semiconductor device.

Here, the semiconductor layer 182 is preferably thicker than at least the oxide layer 181. The thicker the semiconductor layer 182 is, the larger the on-state current of the transistor is. The thickness of the oxide layer 181 may be set as appropriate as long as formation of an interface state at an interface with the semiconductor layer 182 is inhibited. For example, the thickness of the semiconductor layer 182 is larger than that of the oxide layer 181, preferably 2 times or more, further preferably 4 times or more, still further preferably 6 times or more as large as that of the oxide layer 181. Note that the above does not apply in the case where the on-state current of the transistor does not need to be increased, and the thickness of the oxide layer 181 may be larger than or equal to that of the semiconductor layer 182.

The thickness of the oxide layer 183 may be set as appropriate, in a manner similar to that of the oxide layer 181, as long as formation of an interface state at an interface with the semiconductor layer 182 is inhibited. For example, the thickness of the oxide layer 183 may be set smaller than or equal to that of the first oxide layer 181. The oxide layer 183 preferably has a small thickness because the thick oxide layer 183 might make it difficult for an electric field by the gate electrode 105 to extend to the semiconductor layer 182. For example, the oxide layer 183 may be thinner than the semiconductor layer 182. Note that the thickness of the oxide layer 183 is not limited to the above, and may be set as appropriate depending on a driving voltage of the transistor in consideration of the withstanding voltage of the insulating layer 104 and the like.

### Modification Example 2-4

A transistor 190 illustrated in FIG. 7B includes an oxide layer 191 and a semiconductor layer 192 instead of the semiconductor layer 120 as in the transistor 150 illustrated in FIGS. 4A to 4C; and further includes an oxide layer 193 between the semiconductor layer 192 and the insulating layer 104.

The single crystal oxide film 110 described in the above embodiment can be used for the oxide layer 191. Further, the oxide film 112 described in the above embodiments can be used for the semiconductor layer 192 and the oxide layer 193.

In addition, the oxide layers 191 and 193 are preferably formed using the same material that contained in the oxide layers 181 and 183 in the above structure example.

With such a structure, the formation of trap states at the interfaces on the insulating layer 104 side and on the substrate 101 side of the semiconductor layer 192 in which the channel is formed is suppressed; thus, it is possible to reduce variation in the electrical characteristics of the transistor 190, which enables a high reliable semiconductor device.

Note that an example of the transistor 190 is illustrated in which the oxide layer 193, the insulating layer 104, and the gate electrode 105 are processed with the use of one photomask so that the shapes of the oxide layer 193, the insulating layer 104, and the gate electrode 105 are substantially aligned with one another when seen from above. With such a structure, there is no need of a photomask for processing the oxide layer 193, so that productivity can be increased.

In this modification example, the single-crystal semiconductor film with good crystallinity formed by the formation method for an oxide film of one embodiment of the present invention is used for the semiconductor layer in which a channel is formed or the oxide layer in contact with the semiconductor layer. Therefore, variation in characteristics can be reduced and a change in electric characteristics of the transistor can be effectively suppressed as compared with the case of, for example, using a polycrystal having crystal grain boundaries; accordingly, a transistor with extremely high reliability is obtained.

The above is the description of this modification example.

### [Example of Manufacturing Method]

An example of a method for manufacturing a transistor is described below. Here, the transistor 150 illustrated in FIGS. 4A to 4C will be described as an example.

### [Formation of Semiconductor Layer]

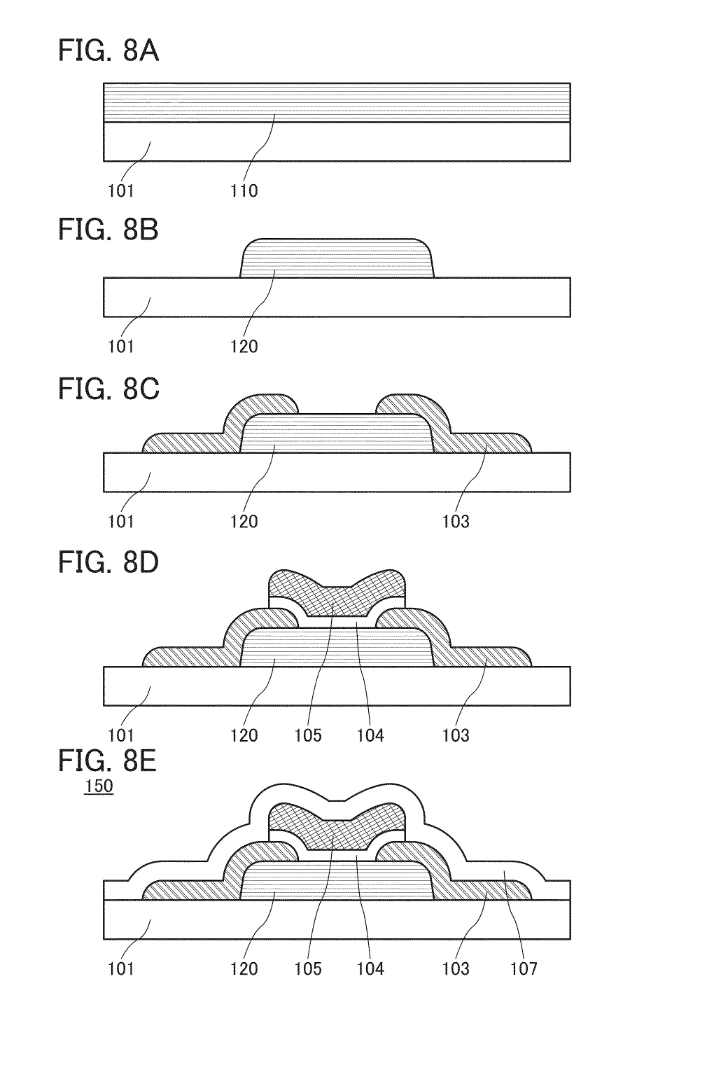

First, the single crystal oxide film 110 is formed over the substrate 101 (see FIG. 8A). The single crystal oxide film 110 can be formed by the formation method described in Embodiment 1 as an example.

Then, a resist mask is formed over the single crystal oxide film 110 by a photolithography process or the like, and unnecessary portions of the single crystal oxide film 110 are removed by etching. Then, the resist mask is removed. Thus, the island-shaped semiconductor layer 120 can be formed (FIG. 8B).

As light used to form the resist mask, light with an i-line (with a wavelength of 365 nm), light with a g-line (with a wavelength of 436 nm), light with an h-line (with a wavelength of 405 nm), or light in which the i-line, the g-line, and the h-line are mixed can be used. Alternatively, ultraviolet light, KrF laser light, ArF laser light, or the like can be used. Exposure may be performed by liquid immersion exposure technique. As the light for the exposure, extreme ultra-violet light (EUV) or X-rays may be used. Instead of the light for the exposure, an electron beam can be used. It is preferable to use extreme ultra-violet light (EUV), X-rays, or an electron beam because extremely minute processing can be performed. Note that in the case of performing exposure by scanning of a beam such as an electron beam, a photomask is not needed.

An organic resin film having a function of improving adhesion between the film to be processed and a resist film may be formed before the resist film serving as a resist mask is formed. The organic resin film can be formed to cover a step under the film by a method such as a spin coating method, and thus can reduce variation in thickness of the resist mask over the organic resin film. In the case of minute processing, in particular, a material serving as a film having a function of preventing reflection of light for the exposure is preferably used for the organic resin film. Examples of the organic resin film having such a function include a bottom anti-reflection coating (BARC) film. The organic resin film may be removed at the same time as the resist mask or after the removal of the resist mask.

As the mask used for etching the film to be processed such as a single crystal oxide film 110, a hard mask made of an inorganic film or a metal film may be used. For example, an inorganic film or a metal film is formed over the film to be processed and the inorganic film or the metal film is etched using a resist mask to be processed into an island shape, whereby the hard mask is formed. Then, the film to be processed is etched using the hard mask as a mask and the hard mask is removed, so that the film to be processed may be processed into a desired shape. In the case of minutely processing the film to be processed, in particular, by using the hard mask, a reduction in pattern width in accordance with side-etching of the resist and the like can be suppressed and the stable shape can be obtained; thus, variation in the electrical characteristics of a transistor can be reduced.

### [Formation of a Pair of Electrodes]

Next, a conductive film is formed over the substrate 101 and the semiconductor layer 120. A resist mask is formed over the conductive film by photolithography or the like, an unnecessary portion is removed by etching, and then the resist mask is removed. Then, the resist mask is removed. Thus, the pair of electrodes 103 can be formed (see FIG. 8C).

The conductive film can be formed by a sputtering method, an evaporation method, or a CVD method (including a MOCVD method), for example.

A sputtering method is preferably used because devices can be made larger easily and productivity can be improved. Further, when a CVD method (a MOCVD method) is used, damage to the semiconductor layer 120 is reduced, whereby a transistor with high reliability can be obtained without reducing crystallinity of the semiconductor layer 120.

Here, in some cases, part of the upper portion of the semiconductor layer 120 is etched in the etching of the conductive film to reduce the thickness of a portion where the pair of electrodes 103 does not overlap with the semiconductor layer 120. The single crystal oxide film 110 to be the semiconductor layer 120 is preferably formed to have a large thickness in advance in consideration of the thickness to be etched.

### [Formation of Gate Insulating Layer and Gate Electrode]

Next, an insulating film to be the insulating layer 104 later is formed over the substrate 101, the semiconductor layer 120, and the pair of electrodes 103. Then, a conductive film to be the gate electrode 105 is formed over the insulating film.

The insulating film to be the insulating layer 104 can be formed by a sputtering method, a CVD method, a molecular beam epitaxy (MBE) method, an atomic layer deposition (ALD) method, a pulsed laser deposition (PLD) method, or the like. In particular, it is preferable that the insulating film be formed by a CVD method, further preferably a plasma CVD method because coverage can be further improved.

In order to make the insulating layer 104 excessively contain oxygen, an insulating film to be the insulating layer 104 may be formed in an oxygen atmosphere, for example. Alternatively, a region excessively containing oxygen may be formed by introducing oxygen into the insulating film that has been formed. Both the methods may be combined.

For example, oxygen (at least including any of oxygen radicals, oxygen atoms, and oxygen ions) is introduced into the insulating film that has been formed, whereby a region excessively containing oxygen is formed. Oxygen can be introduced by an ion implantation method, an ion doping method, a plasma immersion ion implantation method, plasma treatment, or the like.

A gas containing oxygen can be used for oxygen introducing treatment. As the gas containing oxygen, oxygen, dinitrogen monoxide, nitrogen dioxide, carbon dioxide, carbon monoxide, and the like can be used. Further, a rare gas may be included in the gas containing oxygen for the oxygen introduction treatment.

The thickness of the insulating layer 104 may be determined depending on the desired electrical characteristics of a transistor; however, the thickness of the insulating layer 104 is preferably as large as possible because the amount of oxygen released is increased. Therefore, it is preferable that the insulating layer 104 be formed to be thick enough not to affect the productivity. It is preferable that the thickness of the insulating layer 104 be, for example, greater than or equal to 50 nm, further preferably greater than or equal to 100 nm, still further preferably greater than or equal to 200 nm.

The conductive film can be formed by a sputtering method, an evaporation method, or a CVD method (including a MOCVD method), for example.

Next, a resist mask is formed over the conductive film by a photolithography method or the like. After that, an unnecessary portion of the conductive film is removed by etching, whereby the gate electrode 105 is formed. Then, the insulating film is etched with the use of the gate electrode 105 or the resist mask as a mask, whereby the insulating layer 104 is formed. The resist mask may be removed after the gate electrode 105 is processed or after the insulating layer 104 is processed. In this manner, the insulating layer 104 and the gate electrode 105 can be formed (see FIG. 8D).

### [Formation of Insulating Layer]

Next, the insulating layer 107 is formed to cover the insulating layer 104, the gate electrode 105, the pair of the electrodes 103, and the like (see FIG. 8E).

The insulating layer 107 can be formed by a sputtering method, a CVD method, an MBE method, an ALD method, a PLD method, or the like. In particular, it is preferable that the insulating layer 107 be formed by a CVD method, more preferably a plasma CVD method because coverage can be favorable.

Through the above process, the transistor 150 can be manufactured.

### [Heat Treatment]

A heat treatment may be performed after the insulating layer 107 is formed. Through the heat treatment, oxygen can be supplied from the insulating layer 104 and the like to the semiconductor layer 120 to reduce oxygen vacancies in the semiconductor layer 120. At this time, oxygen released from the insulating layer 104 and the semiconductor layer 120 is effectively confined in the insulating layer 107, and release of oxygen to the outside is suppressed. Thus, the amount of oxygen released from the insulating layer 104 and the like and supplied to the semiconductor layer 120 can be increased, so that the oxygen vacancies in the semiconductor layer 120 can be effectively reduced.

Here, in the case where a stacked structure in which two or more layers are stacked is provided instead of the semiconductor layer 120 as illustrated in FIGS. 5A to 5C and FIGS. 7A and 7B, after the single crystal oxide film 110 is formed over the substrate 101, one or more oxide films illustrated in Embodiment 1 may be formed, whereby stacked films are formed, and the stacked films may be processed into an island-like shape. The oxide film can be formed by a sputtering method, a CVD method, an MBE method, an ALD method, a PLD method, or the like.

Further, in the case of providing an oxide layer between the insulating layer 104 and the semiconductor layer as illustrated in FIGS. 6A to 6C and FIG. 7B, the oxide film may be formed before the insulating film to be the insulating layer 104 is formed. Further, the oxide film and the gate electrode 105 may be processed with use of one mask, or the oxide film may be processed with the use of a mask having a pattern including a pattern of the gate electrode 105. In addition, oxygen may be supplied to the oxide film, so that the oxide film may be an oxide film from which oxygen is released by heating.

At least part of this embodiment can be implemented in combination with any of the embodiments described in this specification as appropriate.

### Embodiment 3

In this embodiment, an example of a circuit to which any of the transistors described in the above embodiments is applicable is described.

A circuit including a transistor using a first semiconductor material and a transistor using a second semiconductor material is described below.

The first semiconductor material and the second semiconductor material are preferably materials having different band gaps. For example, a semiconductor material other than an oxide semiconductor (e.g., silicon, germanium, silicon germanium, silicon carbide, or gallium arsenide) can be used as the first semiconductor material, and an oxide semiconductor can be used as the second semiconductor material. A transistor using a material other than an oxide semiconductor, such as single crystal silicon, can operate at high speed easily. On the other hand, a transistor including an oxide semiconductor has a low off-state current.

The transistor using the first semiconductor material may be either an n-channel transistor or a p-channel transistor, and an appropriate transistor may be used in accordance with a circuit.

Any of the transistors described in the above embodiments can be used as the transistor using the second semiconductor material.

### Circuit Configuration Example

Examples of circuit configurations which can be achieved by using a semiconductor device of one embodiment of the present invention are shown below.

### [CMOS Circuit]

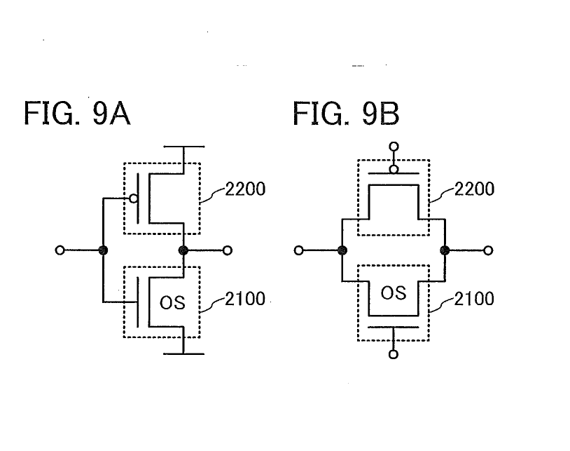

A circuit diagram in FIG. 9A shows a configuration of what is called a CMOS circuit in which a p-channel transistor 2200 including the first semiconductor material and a n-channel transistor 2100 including the second semiconductor material are connected to each other in series and in which gates of them are connected to each other.

### [Analog Switch]

A circuit diagram in FIG. 9B shows a configuration in which sources of the transistors 2100 and 2200 are connected to each other and drains of the transistors 2100 and 2200 are connected to each other. With such a configuration, the transistors can function as what is called an analog switch.

### [Example of Memory Device]

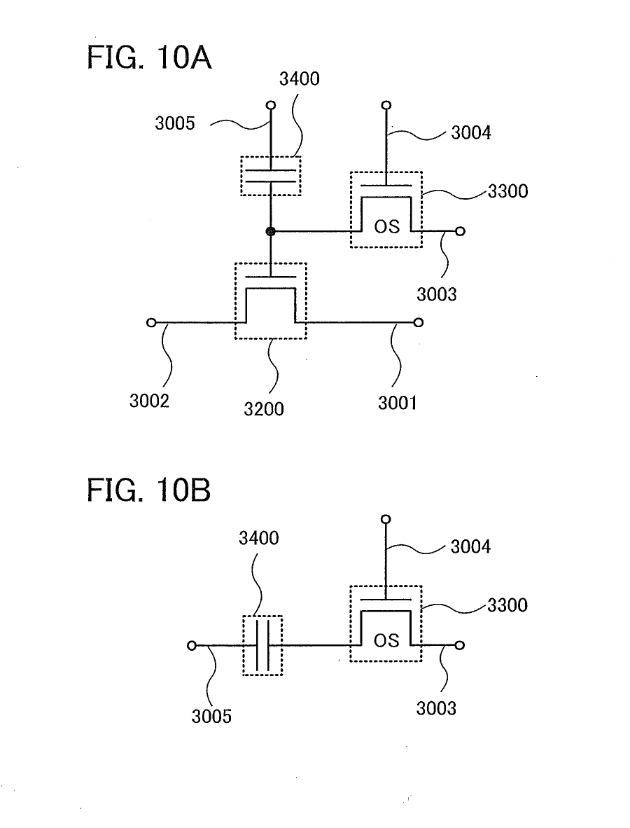

In this embodiment, an example of a semiconductor device (memory device) which includes a transistor of one embodiment of the present invention, which can retain stored data even when not powered, and which has an unlimited number of write cycles is described with reference to FIGS. 10A and 10B.

A semiconductor device illustrated in FIG. 10A includes a transistor 3200 using the first semiconductor material, a transistor 3300 using the second semiconductor material, and a capacitor 3400. Note that as the transistor 3300, any of the transistors described in the above embodiments can be used.

The transistor 3300 is a transistor in which a channel is formed in a semiconductor layer including an oxide semiconductor. Since the off-state current of the transistor 3300 is low, stored data can be retained for a long period owing to such a transistor. In other words, power consumption can be sufficiently reduced because a semiconductor memory device in which refresh operation is unnecessary or the frequency of refresh operation is extremely low can be provided.

In FIG. 10A, a first wiring 3001 is electrically connected to a source electrode of the transistor 3200. A second wiring 3002 is electrically connected to a drain electrode of the transistor 3200. A third wiring 3003 is electrically connected to one of a source electrode and a drain electrode of the transistor 3300. A fourth wiring 3004 is electrically connected to a gate electrode of the transistor 3300. A gate electrode of the transistor 3200 and the other of the source electrode and the drain electrode of the transistor 3300 are electrically connected to one electrode of the capacitor 3400. A fifth wiring 3005 is electrically connected to the other electrode of the capacitor 3400.

The semiconductor device in FIG. 10A utilizes a characteristic in which the potential of the gate electrode of the transistor 3200 can be held, and thus enables writing, holding, and reading of data as follows.

Writing and holding of data is described. First, the potential of the fourth wiring 3004 is set to a potential at which the transistor 3300 is turned on, so that the transistor 3300 is turned on. Accordingly, the potential of the third wiring 3003 is supplied to the gate electrode of the transistor 3200 and the capacitor 3400. That is, predetermined charge is supplied to the gate electrode of the transistor 3200 (writing). Here, charge for supplying either of two different potential levels (hereinafter referred to as low-level charge and high-level charge) is given. Then, the potential of the fourth wiring 3004 is set to a potential at which the transistor 3300 is turned off, so that the transistor 3300 is turned off. Thus, the charge given to the gate electrode of the transistor 3200 is held (holding).

Since the off-state current of the transistor 3300 is extremely small, the charge of the gate electrode of the transistor 3200 is held for a long time.

Next, reading of data is described. By supplying an appropriate potential (a reading potential) to the fifth wiring 3005 while supplying a predetermined potential (a constant potential) to the first wiring 3001, the potential of the second wiring 3002 varies depending on the amount of charge held in the gate electrode of the transistor 3200. This is because in general, when the transistor 3200 is an n-channel transistor, an apparent threshold voltage Vₜₕ_{_{—}}_{H} in the case where a high-level charge is given to the gate electrode of the transistor 3200 is lower than an apparent threshold voltage Vₜₕ_{_{—}}_{L} in the case where a low-level charge is given to the gate electrode of the transistor 3200. Here, an apparent threshold voltage refers to the potential of the fifth wiring 3005 which is needed to turn on the transistor 3200. Thus, the potential of the fifth wiring 3005 is set to a potential V₀ which is between Vₜₕ_{_{—}}_{H} and Vₜₕ_{_{—}}_{L}, whereby charge supplied to the gate electrode of the transistor 3200 can be determined. For example, in the case where the high-level charge is supplied in writing, when the potential of the fifth wiring 3005 is V₀ (>Vₜₕ_{_{—}}_{H}), the transistor 3200 is turned on. In the case where the low-level charge is supplied in writing, even when the potential of the fifth wiring 3005 is V₀ (<Vₜₕ_{_{—}}_{L}), the transistor 3200 remains off. Therefore, the data stored in the gate electrode layer can be read by determining the potential of the second wiring 3002.

Note that in the case where memory cells are arrayed to be used, only data of desired memory cells needs to be read. In the case where such reading is not performed, a potential at which the transistor 3200 is off regardless of the state of the gate electrode, that is, a potential smaller than Vₜₕ_{_{—}}_{H} may be applied to the fifth wiring 3005. Alternatively, a potential at which the transistor 3200 is on regardless of the state of the gate electrode, that is, a potential larger than Vₜₕ_{_{—}}_{L} may be applied to the fifth wiring 3005.

The semiconductor device illustrated in FIG. 10B is different from the semiconductor device illustrated in FIG. 10A mainly in that the transistor 3200 is not provided. Also in this case, writing and holding of data can be performed in a manner similar to the above.

Next, operation of data reading is described. When the transistor 3300 is turned on, the third wiring 3003 which is in a floating state and the capacitor 3400 are electrically connected to each other, and the charge is redistributed between the third wiring 3003 and the capacitor 3400. As a result, the potential of the third wiring 3003 is changed. The amount of change in potential of the third wiring 3003 varies depending on the potential of the first terminal of the capacitor 3400 (or the charge accumulated in the capacitor 3400).

For example, the potential of the third wiring 3003 after the charge redistribution is (C_{B}×V_{B0}+C×V)/(C_{B}+C), where V is the potential of the first terminal of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the first terminal of the capacitor 3400 is V₁ and V₀ (V₁>V₀), the potential of the third wiring 3003 in the case of retaining the potential V₁ (=(C_{B}×V_{B0}+C×V₁)/(C_{B}+C)) is higher than the potential of the third wiring 3003 in the case of retaining the potential V₀ (=(C_{B}×V_{B0}+C×V₀)/(C_{B}+C)).

Then, by comparing the potential of the third wiring 3003 with a predetermined potential, data can be read.

In this case, a transistor including the first semiconductor material may be used for a driver circuit for driving a memory cell, and a transistor including the second semiconductor material may be stacked over the driver circuit as the transistor 3300.

When a transistor having a channel formation region formed using an oxide semiconductor and having extremely small off-state current is applied to the semiconductor device in this embodiment, the semiconductor device can store data for an extremely long period. In other words, power consumption can be sufficiently reduced because refresh operation becomes unnecessary or the frequency of refresh operation can be extremely low. Moreover, stored data can be held for a long period even when power is not supplied (note that a potential is preferably fixed).

Furthermore, in the semiconductor device described in this embodiment, high voltage is not needed for writing data and there is no problem of deterioration of elements. For example, unlike a conventional non-volatile memory, it is not necessary to inject and extract electrons into and from a floating gate, and thus a problem such as deterioration of a gate insulating layer does not occur at all. In other words, the semiconductor device according to one embodiment of the present invention does not have a limit on the number of times of writing which is a problem in a conventional nonvolatile memory, and reliability thereof is drastically improved. Furthermore, data is written depending on the on state and the off state of the transistor, whereby high-speed operation can be easily achieved.

At least part of this embodiment can be implemented in combination with any of the embodiments described in this specification as appropriate.

### Embodiment 4

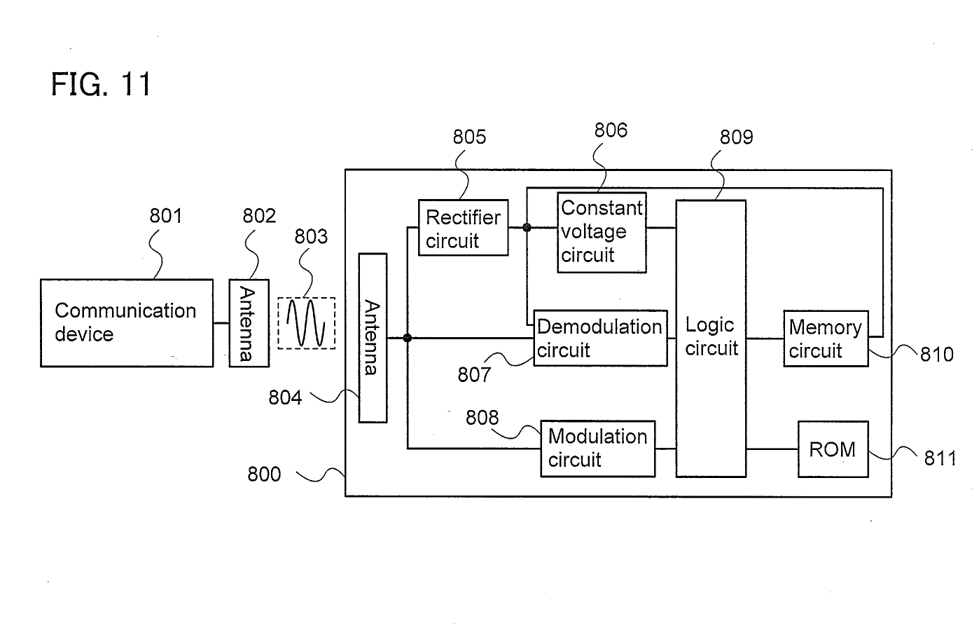

In this embodiment, an RFID tag that includes any of the transistors described in the above embodiments or the memory device described in the above embodiment is described with reference to FIG. 11.

An RFID tag in this embodiment includes a memory circuit inside, stores data which is necessary for the memory circuit, and transmits and receives data to/from the outside by using contactless means, for example, wireless communication. With these characteristics, an RFID tag can be used for an individual authentication system in which an object or the like is recognized by reading the individual information, for example. In order that an RFID tag is used for such application, extremely high reliability is needed.

A configuration of the RFlD tag is described with reference to FIG. 11. FIG. 11 is a block diagram illustrating a configuration example of the RFID tag.

As shown in FIG. 11, an RFID tag 800 includes an antenna 804 which receives a radio signal 803 that is transmitted from an antenna 802 connected to a communication device 801 (also referred to as an interrogator, a reader/writer, or the like). The RFID tag 800 includes a rectifier circuit 805, a constant voltage circuit 806, a demodulation circuit 807, a modulation circuit 808, a logic circuit 809, a memory circuit 810, and a ROM 811. A transistor having a rectifying function included in the demodulation circuit 807 may include a material which enables a reverse current to be small enough, for example, an oxide semiconductor. This can suppress the phenomenon of a rectifying function becoming weaker due to generation of a reverse current and prevent saturation of the output from the demodulation circuit. In other words, the input to the demodulation circuit and the output from the demodulation circuit can have a relation closer to a linear relation. Note that data transmission methods are roughly classified into the following three methods: an electromagnetic coupling method by which a pair of coils is provided so as to be faced with each other and communicates with each other by mutual induction, an electromagnetic induction method by which communication is performed using an induction field, and an electric wave method by which communication is performed using an electric wave. The RFID tag 800 in this embodiment can be used for any one of these methods.

Next, a structure of each circuit will be described. The antenna 804 exchanges the radio signal 803 with the antenna 802 which is connected to the communication device 801. The rectifier circuit 805 generates an input potential by rectification, for example, half-wave voltage doubler rectification of an input alternating signal generated by reception of a radio signal at the antenna 804 and smoothing of the rectified signal with a capacitor provided in a later stage in the rectifier circuit 805. Note that a limiter circuit may be provided on an input side or an output side of the rectifier circuit 805. The limiter circuit controls electric power so that electric power which is higher than or equal to certain electric power is not input to a circuit in a later stage if the amplitude of the input alternating signal is high and an internal generation voltage is high.

The constant voltage circuit 806 generates a stable power supply voltage from an input potential and supplies it to each circuit. Note that the constant voltage circuit 806 may include a reset signal generation circuit. The reset signal generation circuit is a circuit which generates a reset signal of the logic circuit 809 by utilizing rise of the stable power supply voltage.

The demodulation circuit 807 demodulates the input alternating signal by envelope detection and generates the demodulated signal. Furthermore, the modulation circuit 808 performs modulation in accordance with data to be output from the antenna 804.

The logic circuit 809 analyzes and processes the demodulated signal. The memory circuit 810 holds the input data and includes a row decoder, a column decoder, a memory region, and the like. The ROM 811 stores an identification number (ID) or the like and outputs it in accordance with processing.

Note that decision whether each circuit described above is provided or not can be made as appropriate as needed.

Here, the memory circuit described in the above embodiment can be used for the memory circuit 810. Since the memory circuit of one embodiment of the present invention can retain data even when not powered, the memory device can be favorably used for an RFID tag. Moreover, the memory circuit of one embodiment of the present invention needs power (voltage) needed for data writing extremely lower than that needed in a conventional nonvolatile memory; thus, it is possible to prevent a difference between the maximum communication range in data reading and that in data writing. Furthermore, it is possible to suppress malfunction or incorrect writing which is caused by power shortage in data writing.

Since the memory circuit of one embodiment of the present invention can be used as a nonvolatile memory, it can also be used as the ROM 811. In this case, it is preferable that a manufacturer separately prepare a command for writing data to the ROM 811 so that a user cannot rewrite data freely. Since the manufacturer gives identification numbers before shipment and then starts shipment of products, instead of putting identification numbers to all the manufactured RFID tags, it is possible to put identification numbers to only good products to be shipped. Thus, the identification numbers of the shipped products are in series and customer management corresponding to the shipped products is easily performed.

At least part of this embodiment can be implemented in combination with any of the embodiments described in this specification as appropriate.

### Embodiment 5

In this embodiment, a CPU in which at least the transistor described in any of the above embodiments can be used and the memory device described in the above embodiment is included is described.

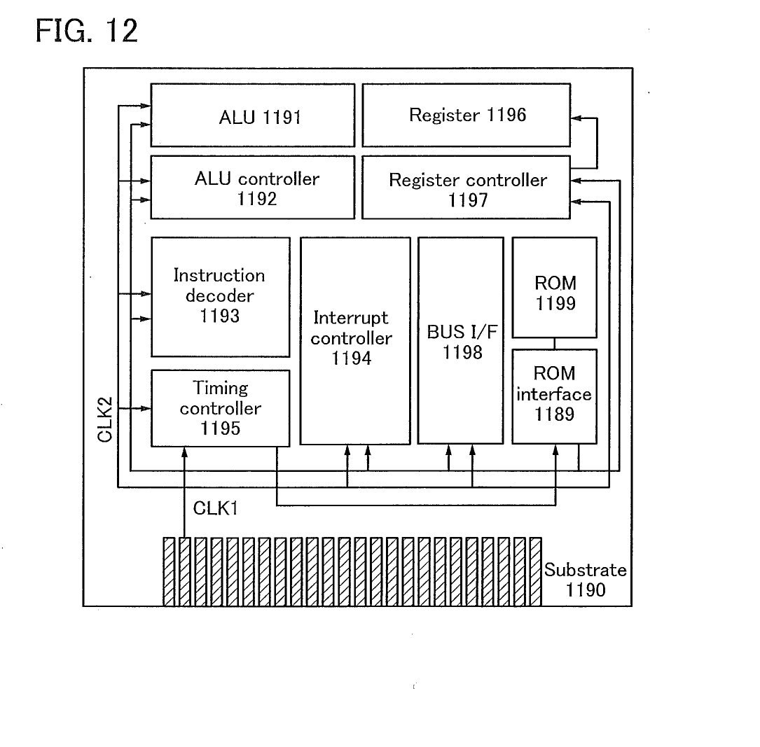

FIG. 12 is a block diagram illustrating an example of the configuration of a CPU at least part of which includes the transistor described in any of the above embodiments.

The CPU illustrated in FIG. 12 includes an arithmetic logic unit (ALU) 1191, an ALU controller 1192, an instruction decoder 1193, an interrupt controller 1194, a timing controller 1195, a register 1196, a register controller 1197, a bus interface (Bus I/F) 1198, a rewritable ROM 1199, and an ROM interface (ROM I/F) 1189 over a substrate 1190. A semiconductor substrate, an SOI substrate, a glass substrate, or the like is used as the substrate 1190. The ROM 1199 and the ROM interface 1189 may be provided over a separate chip. It is needless to say that the CPU illustrated in FIG. 12 is only an example whose configuration is simplified, and actual CPUs have various configurations depending on applications. For example, the CPU may have the following configuration: a structure including the CPU illustrated in FIG. 12 or an arithmetic circuit is considered as one core; a plurality of the cores is included; and the cores operate in parallel. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 processes an interrupt request from an external input/output device or a peripheral circuit depending on its priority or a mask state. The register controller 1197 generates an address of the register 1196, and reads/writes data from/to the register 1196 depending on the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 on the basis of a reference clock signal CLK1, and supplies the internal clock signal CLK2 to the above circuits.

In the CPU illustrated in FIG. 12, a memory cell is provided in the register 1196. For the memory cell of the register 1196, any of the transistors described in the above embodiments can be used.

In the CPU illustrated in FIG. 12, the register controller 1197 selects an operation of holding data in the register 1196, in response to an instruction from the ALU 1191. That is, the register controller 1197 selects whether data is held by a flip-flop or by a capacitor in the memory cell included in the register 1196. When data holding by the flip-flop is selected, a power supply voltage is supplied to the memory cell in the register 1196. When data holding by the capacitor is selected, the data is rewritten in the capacitor, and supply of power supply voltage to the memory cell in the register 1196 can be stopped.

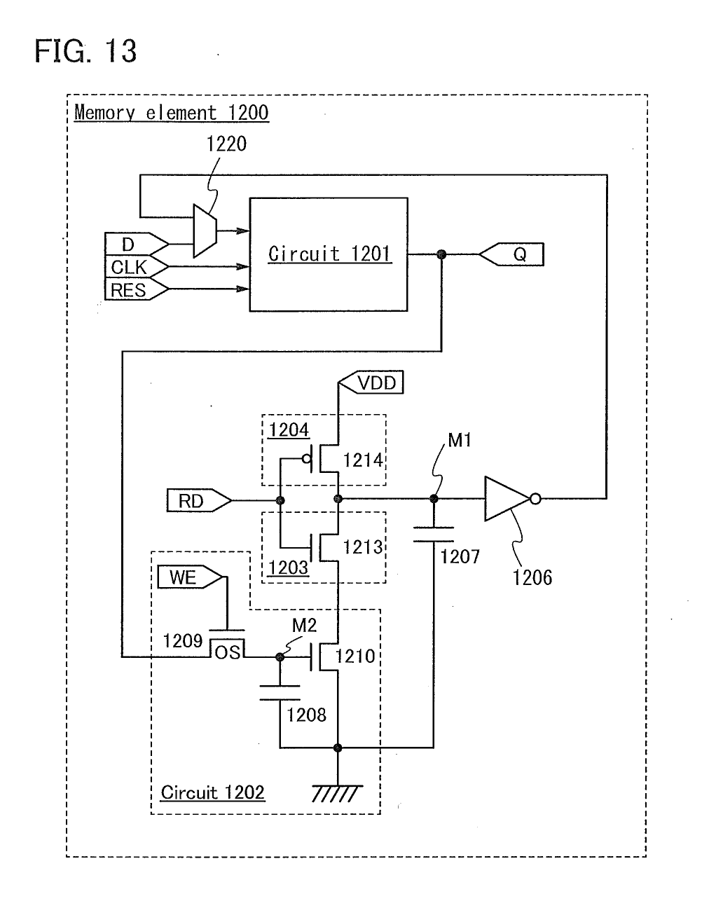

FIG. 13 is an example of a circuit diagram of a memory element that can be used as the register 1196. A memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the memory device described in the above embodiment can be used as the circuit 1202. When supply of a power supply voltage to the memory element 1200 is stopped, a ground potential (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a line which can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a line which can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g. GND) or a high power supply potential (e.g., VDD). The other of the pair of electrodes of the capacitor 1207 is electrically connected to the line which can supply a low power supply potential (e.g., a GND line). The other of the pair of electrodes of the capacitor 1208 can be supplied with a constant potential. For example, the other of the pair of electrodes of the capacitor 1208 can be supplied with a low power supply potential (e.g., GND) or a high power supply potential (e.g., VDD). The other of the pair of electrodes of the capacitor 1208 is electrically connected to the line which can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to a gate (a gate electrode) of the transistor 1209. As for each of the switch 1203 and the switch 1204, a conduction state or a non-conduction state between the first terminal and the second terminal is selected by the control signal RD which is different from the control signal WE. When the first terminal and the second terminal of one of the switches are in the conduction state, the first terminal and the second terminal of the other of the switches are in the non-conduction state.

A signal corresponding to data retained in the circuit 1201 is input to the other of the source and the drain of the transistor 1209. FIG. 13 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 13, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 13, the transistors included in the memory element 1200 except for the transistor 1209 can each be a transistor in which a channel is formed in a layer or the substrate 1190 including a semiconductor other than an oxide semiconductor. For example, the transistor can be a transistor in which a channel is formed in a silicon layer or a silicon substrate. Alternatively, all the transistors in the memory element 1200 may be a transistor in which a channel is formed in an oxide semiconductor layer. Further alternatively, in the memory element 1200, a transistor in which a channel is formed in an oxide semiconductor layer can be included besides the transistor 1209, and a transistor in which a channel is formed in a layer or the substrate 1190 including a semiconductor other than an oxide semiconductor can be used for the rest of the transistors.

As the circuit 1201 in FIG. 13, for example, a flip-flop circuit can be used. As the logic element 1206, for example, an inverter or a clocked inverter can be used.

In a period during which the memory element 1200 is not supplied with the power supply voltage, the semiconductor device of one embodiment of the present invention can retain data stored in the circuit 1201 by the capacitor 1208 which is provided in the circuit 1202.

The off-state current of a transistor in which a channel is formed in an oxide semiconductor layer is extremely low. For example, the off-state current of a transistor whose channel is formed in an oxide semiconductor layer is much lower than that of a transistor whose channel is formed in crystalline silicon. Thus, when the transistor is used as the transistor 1209, a signal held in the capacitor 1208 is retained for a long time also in a period during which the power supply voltage is not supplied to the memory element 1200. The memory element 1200 can accordingly retain the stored content (data) also in a period during which the supply of the power supply voltage is stopped.

Since the memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Therefore, after supply of the power supply voltage to the memory element 1200 is restarted, the signal retained by the capacitor 1208 can be converted into the one corresponding to the state (the on state or the off state) of the transistor 1210 to be read from the circuit 1202. Consequently, an original signal can be accurately read even when a potential corresponding to the signal retained by the capacitor 1208 varies to some degree.

By applying the above-described memory element 1200 to a memory device such as a register or a cache memory included in a processor, data in the memory device can be prevented from being lost owing to the stop of the supply of the power supply voltage. Furthermore, shortly after the supply of the power supply voltage is restarted, the memory element can be returned to the same state as that before the power supply is stopped. Therefore, the power supply can be stopped even for a short time in the processor or one or a plurality of logic circuits included in the processor. Accordingly, power consumption can be suppressed.

Although an example in which the memory element 1200 is used in the CPU is described in this embodiment, the memory element 1200 can also be used in an LSI such as a digital signal processor (DSP), a custom LSI, or a programmable logic device (PLD), and a radio frequency identification (RF-ID).

At least part of this embodiment can be implemented in combination with any of the embodiments described in this specification as appropriate.

### Embodiment 6

In this embodiment, a structure example of a display panel of one embodiment of the present invention is described.

### Structure Example

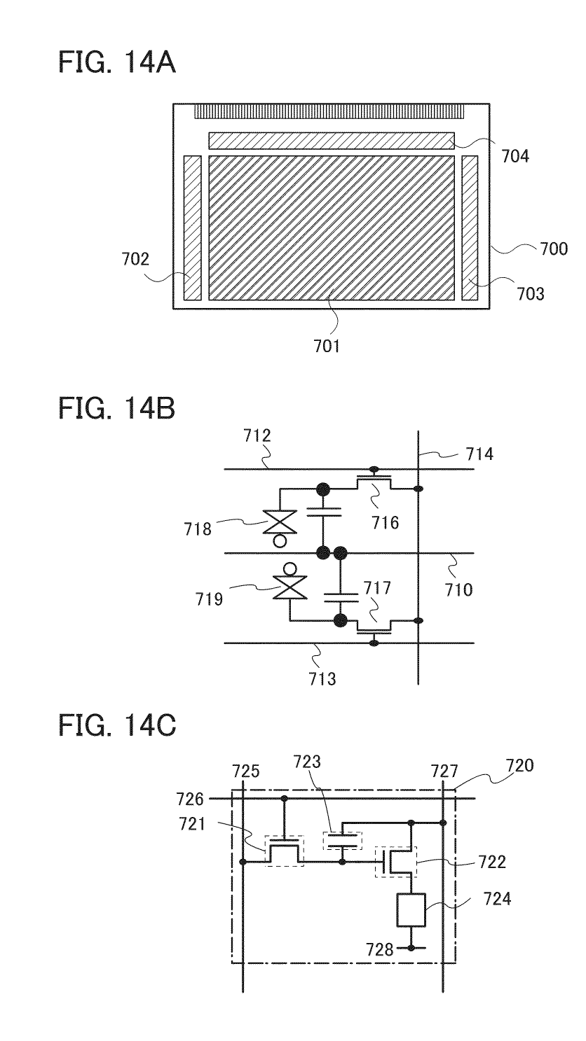

FIG. 14A is a top view of the display panel of one embodiment of the present invention. FIG. 14B is a circuit diagram illustrating a pixel circuit that can be used in the case where a liquid crystal element is used in a pixel in the display panel of one embodiment of the present invention. FIG. 14C is a circuit diagram illustrating a pixel circuit that can be used in the case where an organic EL element is used in a pixel in the display panel of one embodiment of the present invention.

Transistors in a pixel portion can be formed in accordance with the above embodiment. Furthermore, the transistor can easily be an n-channel transistor, and thus, part of a driver circuit that can be formed using an n-channel transistor in the driver circuit is formed over the same substrate as the transistor of the pixel portion. With the use of the transistor described in the above embodiment for the pixel portion or the driver circuit in this manner, a highly reliable display device can be provided.

FIG. 14A illustrates an example of a block diagram of an active matrix display device. A pixel portion 701, a first scan line driver circuit 702, a second scan line driver circuit 703, and a signal line driver circuit 704 are formed over a substrate 700 of the display device. In the pixel portion 701, a plurality of signal lines extended from the signal line driver circuit 704 is arranged and a plurality of scan lines extended from the first scan line driver circuit 702 and the second scan line driver circuit 703 is arranged. Note that pixels each including a display element are provided in matrix in respective regions in each of which the scan line and the signal line intersect with each other. The substrate 700 of the display device is connected to a timing control circuit (also referred to as a controller or a controller IC) through a connection portion such as a flexible printed circuit (FPC).

In FIG. 14A, the first scan line driver circuit 702, the second scan line driver circuit 703, and the signal line driver circuit 704 are formed over the same substrate 700 as the pixel portion 701. Accordingly, the number of components which are outside, such as a driver circuit, can be reduced, so that a reduction in cost can be achieved. Furthermore, if the driver circuit is provided outside the substrate 700, wirings would need to be extended and the number of connections of wirings would be increased, but by providing the driver circuit over the substrate 700, the number of connections of the wirings can be reduced. Consequently, an improvement in reliability or yield can be achieved.

### [Liquid Crystal Panel]

FIG. 14B illustrates an example of a circuit configuration of a pixel. Here, a pixel circuit which is applicable to a pixel of a VA liquid crystal display panel is illustrated.

This pixel circuit can be applied to a structure in which one pixel includes a plurality of pixel electrode layers. The pixel electrode layers are connected to different transistors, and the transistors can be driven with different gate signals. Accordingly, signals applied to individual pixel electrode layers in a multi-domain pixel can be controlled independently.

A gate wiring 712 of a transistor 716 and a gate wiring 713 of a transistor 717 are separated so that different gate signals can be supplied thereto. In contrast, a source or drain electrode layer 714 functioning as a data line is shared by the transistors 716 and 717. The transistor described in the above embodiments can be used as appropriate as each of the transistors 716 and 717. In the above manner, a highly reliable liquid crystal display panel can be provided.

The shapes of a first pixel electrode layer electrically connected to the transistor 716 and a second pixel electrode layer electrically connected to the transistor 717 are described. The first pixel electrode layer and the second pixel electrode layer are separated by a slit. The first pixel electrode layer has a V shape and the second pixel electrode layer is provided so as to surround the first pixel electrode layer.

A gate electrode of the transistor 716 is connected to the gate wiring 712, and a gate electrode of the transistor 717 is connected to the gate wiring 713. When different gate signals are supplied to the gate wiring 712 and the gate wiring 713, operation timings of the transistor 716 and the transistor 717 can be varied. As a result, alignment of liquid crystals can be controlled.

In addition, a storage capacitor may be formed using a capacitor wiring 710, a gate insulating film functioning as a dielectric, and a capacitor electrode electrically connected to the first pixel electrode layer or the second pixel electrode layer.

The multi-domain pixel includes a first liquid crystal element 718 and a second liquid crystal element 719. The first liquid crystal element 718 includes the first pixel electrode layer, a counter electrode layer, and a liquid crystal layer therebetween. The second liquid crystal element 719 includes the second pixel electrode layer, a counter electrode layer, and a liquid crystal layer therebetween.

Note that a pixel circuit of the present invention is not limited to that illustrated in FIG. 14B. For example, a switch, a resistor, a capacitor, a transistor, a sensor, a logic circuit, or the like may be added to the pixel illustrated in FIG. 14B.

### [Organic EL Panel]

FIG. 14C illustrates another example of a circuit configuration of the pixel. Here, a pixel configuration of a display panel using an organic EL element is illustrated.

In an organic EL element, by application of voltage to a light-emitting element, electrons are injected from one of a pair of electrodes and holes are injected from the other of the pair of electrodes, into a layer containing a light-emitting organic compound; thus, current flows. The electrons and holes are recombined, and thus, the light-emitting organic compound is excited. The light-emitting organic compound returns to a ground state from the excited state, thereby emitting light. Based on the mechanism, such a light-emitting element is referred to as a current-excitation type light-emitting element.

FIG. 14C illustrates an applicable example of a pixel circuit. In this example, one pixel includes two n-channel transistors. Note that the metal oxide film of one embodiment of the present invention can be used for channel formation regions of the n-channel transistors. Furthermore, digital time grayscale driving can be employed for the pixel circuit.

The configuration of the applicable pixel circuit and operation of a pixel employing digital time grayscale driving are described.

A pixel 720 includes a switching transistor 721, a driver transistor 722, a light-emitting element 724, and a capacitor 723. A gate electrode layer of the switching transistor 721 is connected to a scan line 726, a first electrode (one of a source electrode layer and a drain electrode layer) of the switching transistor 721 is connected to a signal line 725, and a second electrode (the other of the source electrode layer and the drain electrode layer) of the switching transistor 721 is connected to a gate electrode layer of the driver transistor 722. The gate electrode layer of the driver transistor 722 is connected to a power supply line 727 through the capacitor 723, a first electrode of the driver transistor 722 is connected to the power supply line 727, and a second electrode of the driver transistor 722 is connected to a first electrode (a pixel electrode) of the light-emitting element 724. A second electrode of the light-emitting element 724 corresponds to a common electrode 728. The common electrode 728 is electrically connected to a common potential line provided over the same substrate.

As the switching transistor 721 and the driver transistor 722, the transistor described in the above embodiment can be used as appropriate. In this manner, a highly reliable organic EL display panel can be provided.

The potential of the second electrode (the common electrode 728) of the light-emitting element 724 is set to be a low power supply potential. Note that the low power supply potential is lower than a high power supply potential supplied to the power supply line 727. For example, the low power supply potential can be GND, 0V, or the like. The high power supply potential and the low power supply potential are set to be higher than or equal to the forward threshold voltage of the light-emitting element 724, and the difference between the potentials is applied to the light-emitting element 724, whereby current is supplied to the light-emitting element 724, leading to light emission. The forward voltage of the light-emitting element 724 refers to a voltage at which a desired luminance is obtained, and includes at least forward threshold voltage.

Note that gate capacitance of the driver transistor 722 may be used as a substitute for the capacitor 723, so that the capacitor 723 can be omitted. The gate capacitance of the driver transistor 722 may be formed between the channel formation region and the gate electrode layer.

Next, a signal input to the driver transistor 722 is described. In the case of a voltage-input voltage driving method, a video signal for sufficiently turning on or off the driver transistor 722 is input to the driver transistor 722. In order for the driver transistor 722 to operate in a linear region, voltage higher than the voltage of the power supply line 727 is applied to the gate electrode layer of the driver transistor 722. Note that voltage higher than or equal to voltage which is the sum of power supply line voltage and the threshold voltage Vth of the driver transistor 722 is applied to the signal line 725.

In the case of performing analog grayscale driving, a voltage greater than or equal to a voltage which is the sum of the forward voltage of the light-emitting element 724 and the threshold voltage Vth of the driver transistor 722 is applied to the gate electrode layer of the driver transistor 722. A video signal by which the driver transistor 722 is operated in a saturation region is input, so that current is supplied to the light-emitting element 724. In order for the driver transistor 722 to operate in a saturation region, the potential of the power supply line 727 is set higher than the gate potential of the driver transistor 722. When an analog video signal is used, it is possible to supply current to the light-emitting element 724 in accordance with the video signal and perform analog grayscale driving.

Note that the configuration of the pixel circuit of the present invention is not limited to that illustrated in FIG. 14C. For example, a switch, a resistor, a capacitor, a sensor, a transistor, a logic circuit, or the like may be added to the pixel circuit illustrated in FIG. 14C.

At least part of this embodiment can be implemented in combination with any of the embodiments described in this specification as appropriate.

### Embodiment 7

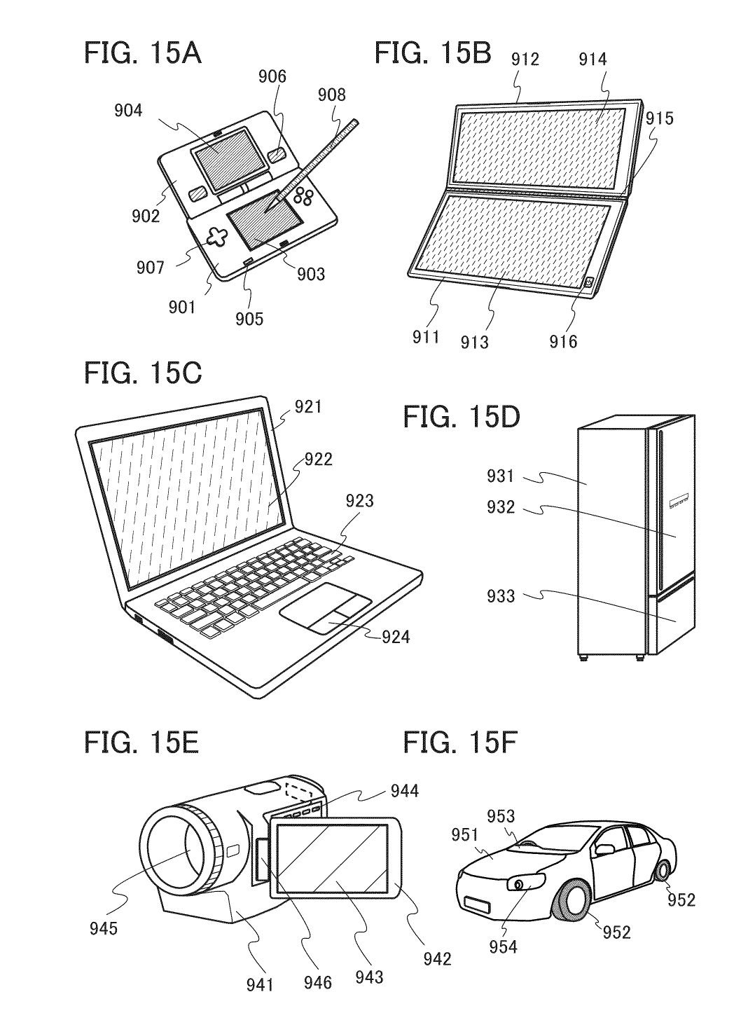

The semiconductor device of one embodiment of the present invention can be used for display devices, personal computers, image reproducing devices provided with recording media (typically, devices which reproduce the content of recording media such as digital versatile discs (DVDs) and have displays for displaying the reproduced images), or the like. Other examples of electronic devices that can be equipped with the semiconductor device of one embodiment of the present invention are mobile phones, game machines including portable game consoles, portable data terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 15A to 15F illustrate specific examples of these electronic devices.

FIG. 15A illustrates a portable game console including a housing 901, a housing 902, a display portion 903, a display portion 904, a microphone 905, a speaker 906, an operation key 907, a stylus 908, and the like. Although the portable game console in FIG. 15A has the two display portions 903 and 904, the number of display portions included in a portable game console is not limited to this.

FIG. 15B illustrates a portable data terminal including a first housing 911, a second housing 912, a first display portion 913, a second display portion 914, a joint 915, an operation key 916, and the like. The first display portion 913 is provided in the first housing 911, and the second display portion 914 is provided in the second housing 912. The first housing 911 and the second housing 912 are connected to each other with the joint 915, and the angle between the first housing 911 and the second housing 912 can be changed with the joint 915. An image on the first display portion 913 may be switched depending on the angle between the first housing 911 and the second housing 912 at the joint 915. A display device with a position input function may be used as at least one of the first display portion 913 and the second display portion 914. Note that the position input function can be added by provision of a touch panel in a display device. Alternatively, the position input function can be added by provision of a photoelectric conversion element called a photosensor in a pixel area of a display device.

FIG. 15C illustrates a laptop personal computer which includes a housing 921, a display portion 922, a keyboard 923, a pointing device 924, and the like.

FIG. 15D illustrates an electric refrigerator-freezer including a housing 931, a door for a refrigerator 932, a door for a freezer 933, and the like.

FIG. 15E illustrates a video camera which includes a first housing 941, a second housing 942, a display portion 943, operation keys 944, a lens 945, a joint 946, and the like. The operation keys 944 and the lens 945 are provided for the first housing 941, and the display portion 943 is provided for the second housing 942. The first housing 941 and the second housing 942 are connected to each other with the joint 946, and the angle between the first housing 941 and the second housing 942 can be changed with the joint 946. An images on the display portion 943 may be switched in accordance with the angle at the joint 946 between the first housing 941 and the second housing 942.

FIG. 15F illustrates a passenger car including a car body 951, wheels 952, a dashboard 953, lights 954, and the like.

At least part of this embodiment can be implemented in combination with any of the embodiments described in this specification as appropriate.

### Embodiment 8

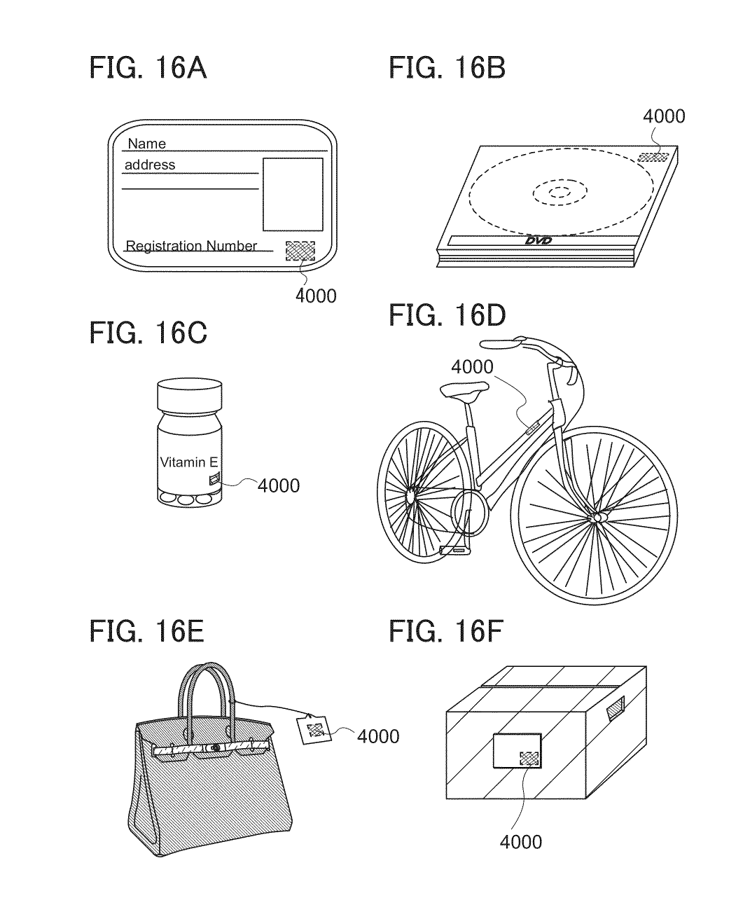

In this embodiment, application examples of an RFID of one embodiment of the present invention are described with reference to FIGS. 16A to 16F. The RFID is widely used and can be provided for, for example, products such as bills, coins, securities, bearer bonds, documents (e.g., driver's licenses or resident's cards, see FIG. 16A), packaging containers (e.g., wrapping paper or bottles, see FIG. 16C), recording media (e.g. DVD software or video tapes, see FIG. 16B), vehicles (e.g., bicycles, see FIG. 16D), personal belongings (e.g., bags or glasses), foods, plants, animals, human bodies, clothing, household goods, medical supplies such as medicine and chemicals, and electronic devices (e.g. liquid crystal display devices, EL display devices, television sets, or mobile phones), or tags on products (see FIGS. 16E and 16F).

An RFID 4000 of one embodiment of the present invention is fixed to a product by being attached to a surface of the product, or embedded in the product. For example, the RFID 4000 is fixed to each product by being embedded in paper of a book, or embedded in an organic resin of a package. Since the RFID 4000 of one embodiment of the present invention can be reduced in size, thickness, and weight, it can be fixed to a product without spoiling the design of the product. Furthermore, bills, coins, securities, bearer bonds, documents, or the like can have an identification function by being provided with the RFID 4000 of one embodiment of the present invention, and the identification function can be utilized to prevent counterfeiting. Moreover, the efficiency of a system such as an inspection system can be improved by providing the RFID of one embodiment of the present invention for packaging containers, recording media, personal belongings, foods, clothing, household goods, electronic devices, or the like. Vehicles can also have higher security against theft or the like by being provided with the RFID of one embodiment of the present invention.

As described above, by using the RFID of one embodiment of the present invention for each application described in this embodiment, power for operation such as writing or reading of data can be reduced, which results in an increase in the maximum communication distance. Moreover, data can be held for an extremely long period even in the state where power is not supplied: thus, the RFID can be preferably used for application in which data is not frequently written or read.

At least part of this embodiment can be implemented in combination with any of the embodiments described in this specification as appropriate.

### Example 1

In this example, a single crystal oxide film was formed by using a method for forming an oxide film of one embodiment of the present invention.

### [Fabrication of Samples]

Three samples, Sample 1, Sample 2, and the Reference Sample 1 described below, were formed.

### [Sample 1]

First, a ZnO film was formed to have a thickness of approximately 2 nm as a buffer film over a YSZ(111) single crystal substrate. The ZnO film was formed by a sputtering method using ZnO as a target. Deposition was performed under the following conditions: the deposition gas was argon, the pressure was 0.4 Pa, the temperature was room temperature, and the DC electric power was 5 kW.

Then, an approximately 100-nm-thick In—Ga—Zn oxide film was formed as an oxide film. The In—Ga—Zn oxide film was formed by a sputtering method using an In—Ga—Zn oxide target (In:Ga:Zn=1:1:5). Deposition was performed under the following conditions: the deposition gas was oxygen, the pressure was 0.4 Pa, the substrate temperature was 300° C., and the DC electric power was 200 W.

Next, heat treatment was performed in the state where a YSZ substrate was provided so as to be in contact with the top surface of the oxide film. The heat treatment was performed at 1400° C. in an air atmosphere using a muffle furnace for 30 minutes. After that, the YSZ substrate provided in the upper part was removed.

### [Sample 2]

To form Sample 2, first, a stack of a ZnO film and an In—Ga—Zn oxide film was formed over a YSZ substrate under conditions similar to those for Sample 1.

Next, heat treatment was performed in a state where a YSZ substrate was provided over the oxide film. The heat treatment was performed at 1200° C. in an oxygen atmosphere for an hour using a vertical furnace.

### [Reference Sample 1]

As Reference Sample 1, a stack of a ZnO film and an In—Ga—Zn oxide film was formed over a YSZ substrate under conditions similar to those for Sample 1. Reference Sample 1 was not subjected to heat treatment.

### [Analysis]

The samples which were formed were observed with X-ray photoelectron spectroscopy (XPS) analysis, X-ray diffraction (XRD) analysis, and scanning transmission electron microscopy (STEM).

### [XPS Analysis Results]

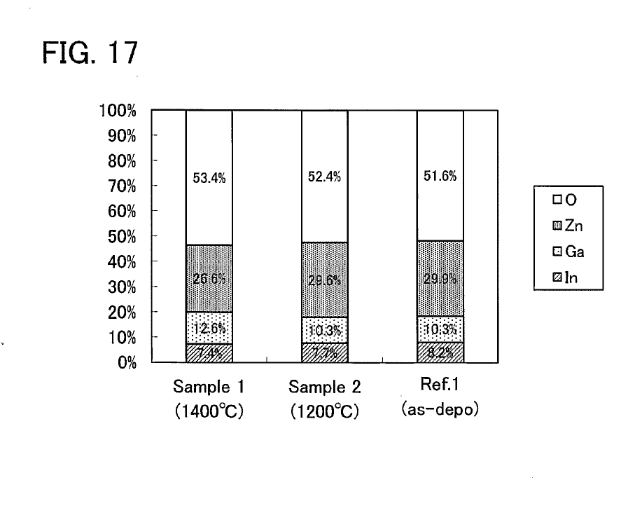

FIG. 17 shows the XPS analysis results of the samples. FIG. 17 illustrates the proportions of the elements, In, Ga, Zn and O in each sample. Table 1 shows the proportion of each element in each sample calculated from FIG. 17 on the assumption that the proportion of In is 1.

TABLE 1

Normalized Composition when In is 1

| Sample | In | Ga | Zn | 0 |
|---|---|---|---|---|
| Sample 1 | 1 | 1.2 | 2.7 | 6.0 |
| (1400° C.) | | | | |
| Sample 2 | 1 | 1.0 | 3.2 | 6.1 |
| (1200° C.) | | | | |
| Ref. 1 | 1 | 1.1 | 3.2 | 6.0 |
| (as-depo) | | | | |

From the result of Reference Sample 1 (Ref. 1) of the Table 1, it can be found that the proportion of Zn is reduced in the oxide film which is just after the deposition compared to that of the sputtering target. While the proportion of Zn of Sample 2 is almost the same as that of Reference Sample 1, Zn in the composition of Sample 1 is reduced compared to Reference Sample 1. Therefore, it is confirmed that the temperature of the heat treatment of at least 1200° C. or lower can suppress the sublimation of Zn.

### [XRD Measurement Results]

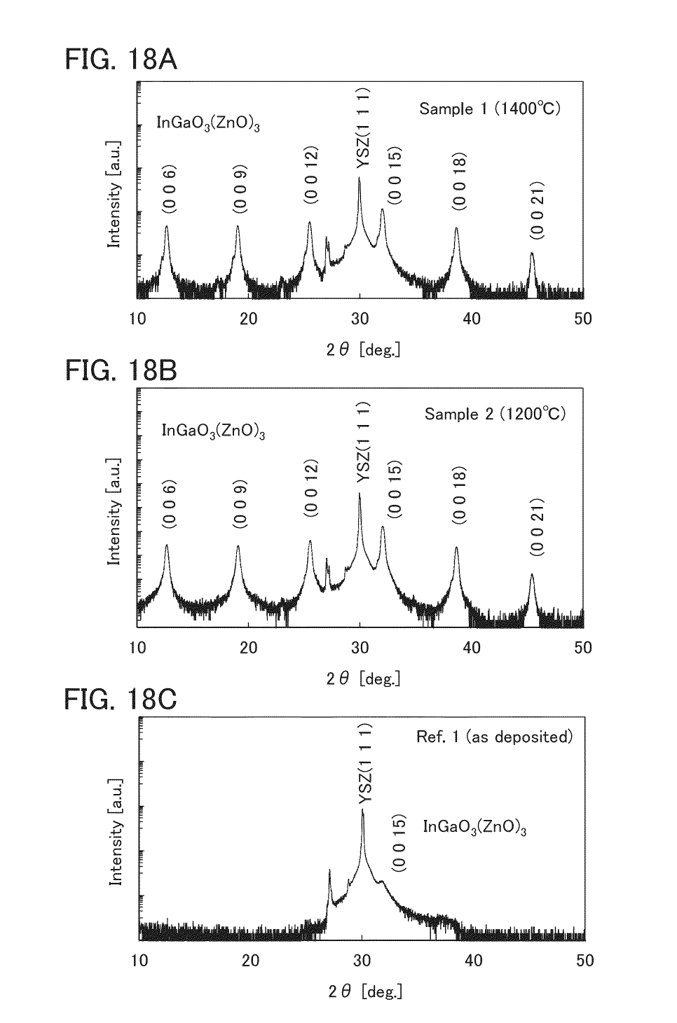

FIGS. 18A to 18C respectively show XRD spectra of Sample 1, Sample 2, and Reference Sample 1 (Ref. 1) measured by an out-of-plane method. In each of FIGS. 18A to 18C, the horizontal axis represents the diffraction angle 20, and the vertical axis represents the X-ray diffraction intensity (arbitrary unit).

It can be found that each peak observed in the XRD spectrum shown in FIGS. 18A and 18B is derived from a plane which is perpendicular to the c-axis of InGaO₃(ZnO)₃. The above results suggest that the c-axis of a crystal is strongly aligned with a normal direction of the formation surface in each of Samples 1 and 2. A peak derived from the (0015) plane of InGaO₃(ZnO)₃ is found in FIG. 18C, and it is also found that Reference Sample 1 has a region in which the c-axis is aligned with a normal direction of the formation surface.

### [STEM Observation Results]

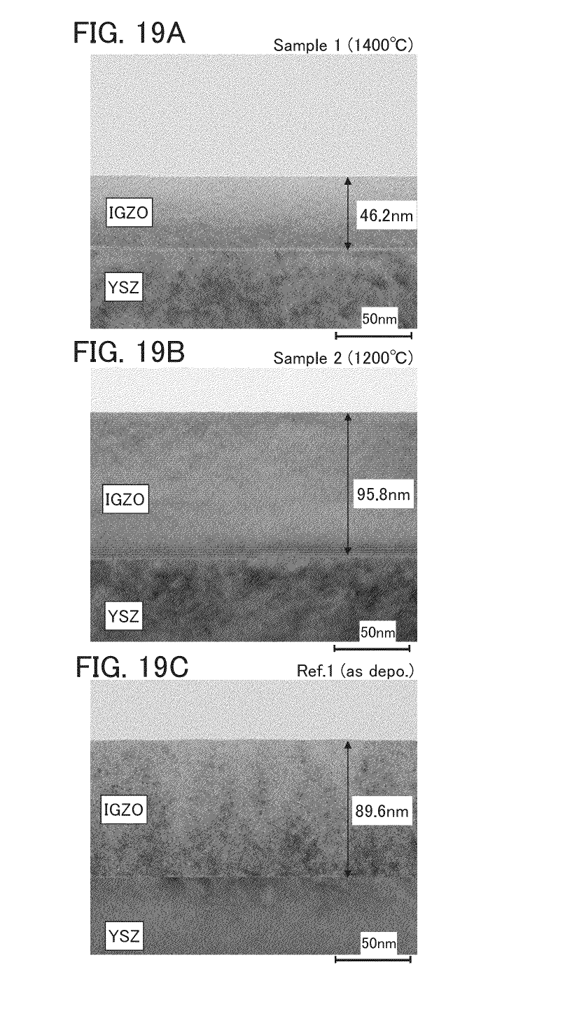

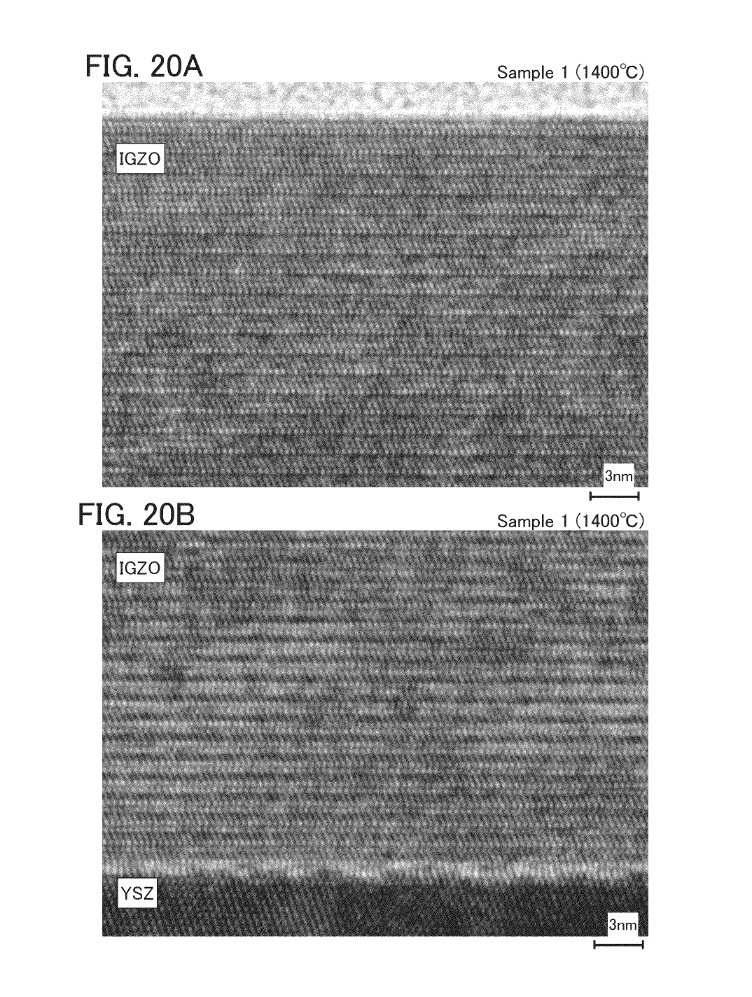

FIGS. 19A to 19C respectively show the cross-sectional images of Sample 1, Sample 2, and Reference Sample 1 (Ref. 1) observed by scanning transmission electron microscopy (STEM). FIGS. 20A and 20B, FIGS. 21A and 21B, and FIGS. 22A and 22B respectively show the results of Sample 1, Sample 2, and Reference Sample 1 which are observed with a high magnification. In each of FIGS. 20A and 20B, FIGS. 21A and 21B, and FIGS. 22A and 22B, Image A shows the vicinity of the surface, and Image B shows the vicinity of the interface with the YSZ substrate.

As seen in FIGS. 19A to 19C, the thickness of the In—Ga—Zn oxide film (also referred to as an IGZO film) of Sample 1 is reduced compared with that of Reference Sample 1 (Ref. 1). This is caused by sublimation of part of the IGZO film due to high temperature of heat treatment at 1400° C. On the other hand, since the thickness of Sample 2 is substantially equal to that of Reference Sample 1, it is confirmed that a reduction in the thickness of the IGZO film can be inhibited effectively by setting the heating temperature to 1200° C.

From FIG. 19A, and FIGS. 20A and 20B, layered stripes are observed in a direction parallel to the formation surface in Sample 1, and a state in which the whole In—Ga—Zn oxide film (IGZO film) is single-crystallized can be found.

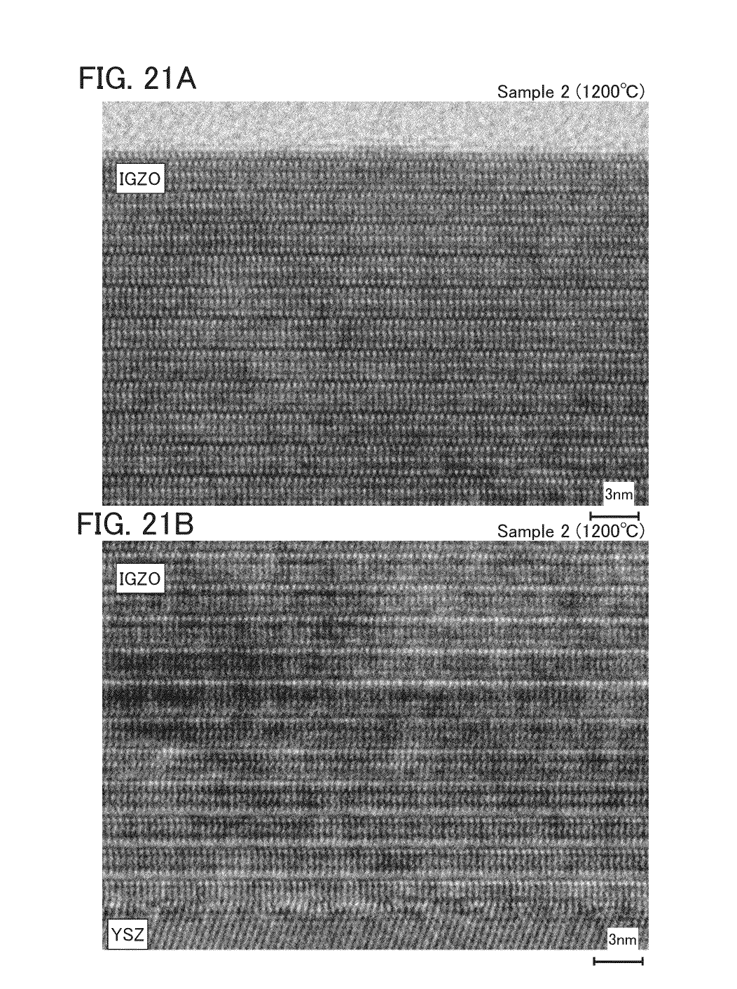

From FIG. 19B, and FIGS. 21A and 21B, in a manner similar to that of Sample 1, layered stripes are observed in a direction parallel to the formation surface, and a state in which the whole IGZO film is single-crystallized can be found in Sample 2.

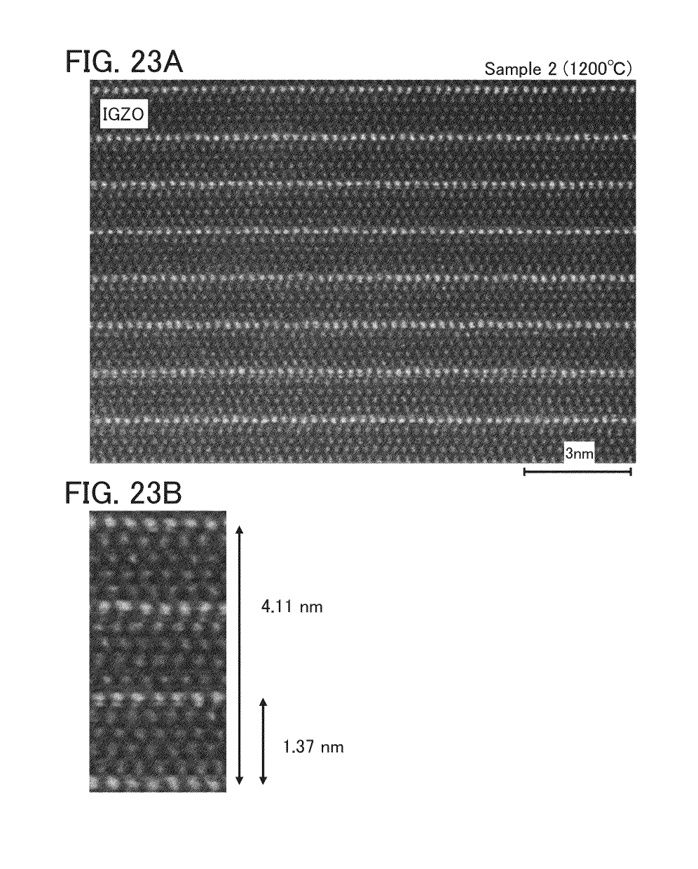

FIGS. 23A and 23B are images of Sample 2 observed by high-angle annular dark field scanning transmission electron microscopy (HAADF-STEM). FIG. 23B is an enlarged view of a part in FIG. 23A.

In FIGS. 23A and 23B, a plurality of layers in which atoms (specifically electrons) with high luminance are arranged periodically and a plurality of layers in which atoms with low luminance are arranged periodically are observed. Here, an atom with high luminance is an In atom, and an atom with low luminance is a Ga atom or a Zn atom.

From FIGS. 23A and 23B, it is found that four layers in which Ga atoms or Zn atoms are arranged exist between layers in which In atoms are arranged. The distance between the layers in which In atoms are arranged is about 1.37 nm. The distance between four layers in which In atoms are aligned corresponding to c-axis of a unit cell of InGaO₃(ZnO)₃ is about 4.11 nm, and the value agrees with a measured value of 4.156 nm listed in M. Nakamura, et. al., J. Solid State Chem. 93, 298 (1991).

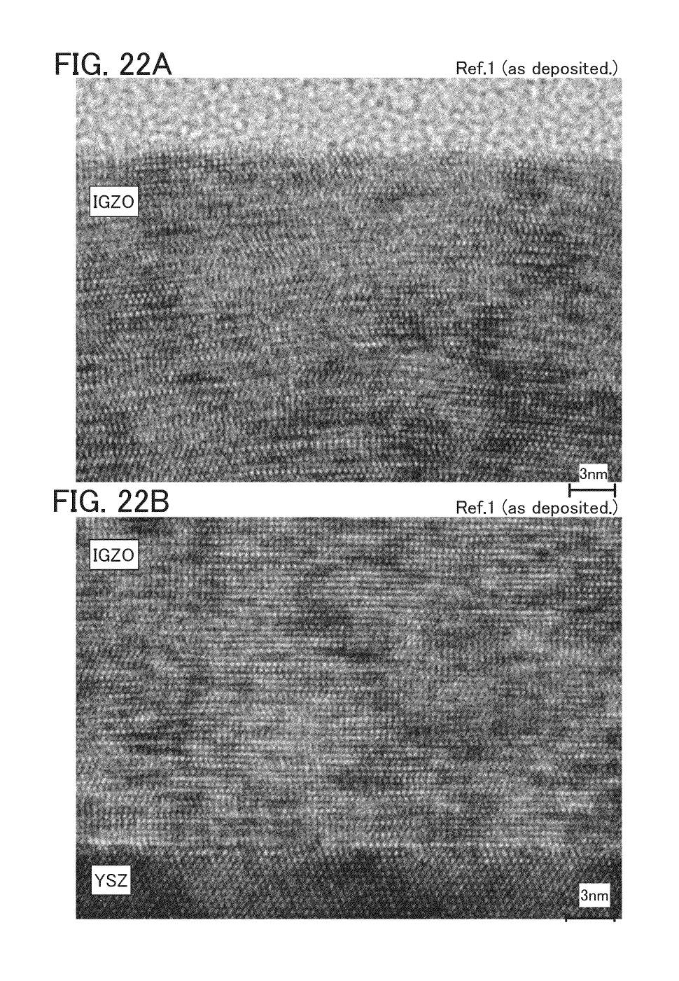

From FIGS. 19C, 22A and 22B, it is found that a large number of regions (crystal parts) in which atoms are aligned with a direction parallel to a formation surface or a surface exist in the IGZO film of Reference Sample 1 (Ref. 1), and that atoms are arranged continuously in each crystal part and a clear crystal grain boundary is not seen in each crystal part.

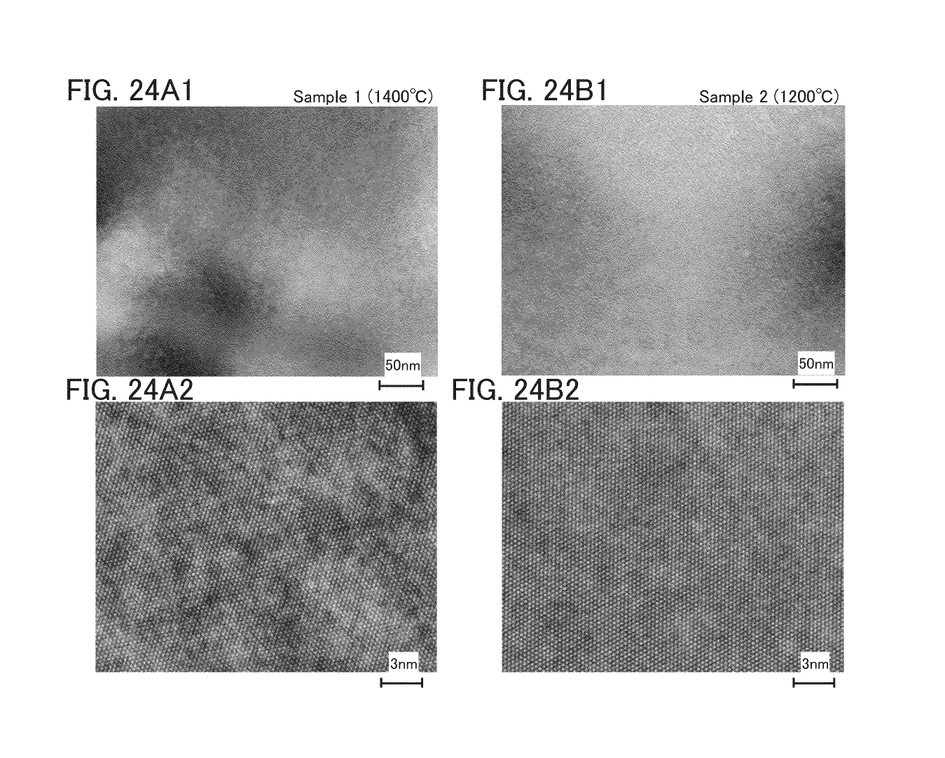

FIGS. 24A1 to 24B2 are STEM images of the surface of IGZO film of Sample 1 and Sample 2. FIGS. 24A1 and A2 are images of Sample 1, and FIGS. 24B1 and B2 are images of Sample 2.

In FIGS. 24A1 and B1, a clear grain boundary is not seen in each of Sample 1 and Sample 2. Further, in FIGS. 24A2 and 24B2 which are high resolution images, a uniform lattice image is observed in each of Sample 1 and Sample 2. Thus, it is found that, in each of Sample 1 and Sample 2, a favorable single crystal IGZO film is formed.

The above results indicate that a favorable single crystal oxide film can be formed by performing heat treatment on an oxide film having crystal parts in which the c-axis are aligned with a direction parallel to the normal direction of the formation surface or a surface, and having no crystal grain boundary between the crystal parts. Further, it is found that a favorable single crystal oxide film can be formed in the case where a buffer layer provided between the oxide film and the substrate is formed by a sputtering method at a room temperature without being subjected to epitaxial growth. It is also found that a favorable single crystal oxide film can be formed at a lower temperature with use of such an oxide film. In particular, it is found that sublimation of part of the oxide film and a difference from stoichiometric composition in the oxide film are effectively suppressed by performing heat treatment at a low temperature.

### Example 2

In this example, a single crystal oxide film is formed without using a buffer film by a method for forming an oxide film according to one embodiment of the present invention.

### [Formation of Samples]

Two samples, Sample 3 and Sample 4 described below, were formed.

### [Sample 3]

An In—Ga—Zn oxide film was formed to have a thickness of approximately 100 nm over a YSZ (111) single crystal substrate. The In—Ga—Zn oxide film was formed by a sputtering method using an In—Ga—Zn oxide target (In:Ga:Zn=1:1:5). Deposition was performed under the following conditions: the deposition gas was oxygen, the pressure was 0.4 Pa, the substrate temperature was 300° C., and the RF electric power was 400 W.

Then, in a manner similar to that of Sample 1, heat treatment was performed at 1400° C. in an air atmosphere using a muffle furnace for 30 minutes in a state where a YSZ substrate was provided over the oxide film. After that, the YSZ substrate provided in the upper part was removed.

### [Sample 4]

An In—Ga—Zn oxide film was formed over a YSZ substrate under conditions similar to those for Sample 3.

Then, in a manner similar to that of Sample 2, heat treatment was performed at 1200° C. in an oxygen atmosphere using a vertical furnace for one hour in a state where a YSZ substrate was provided over the oxide film. After that, the YSZ substrate provided in the upper part was removed.

### [Analysis]

Cross sections of the samples which were formed were observed with XRD and STEM.

### [XRD Measurement Results]

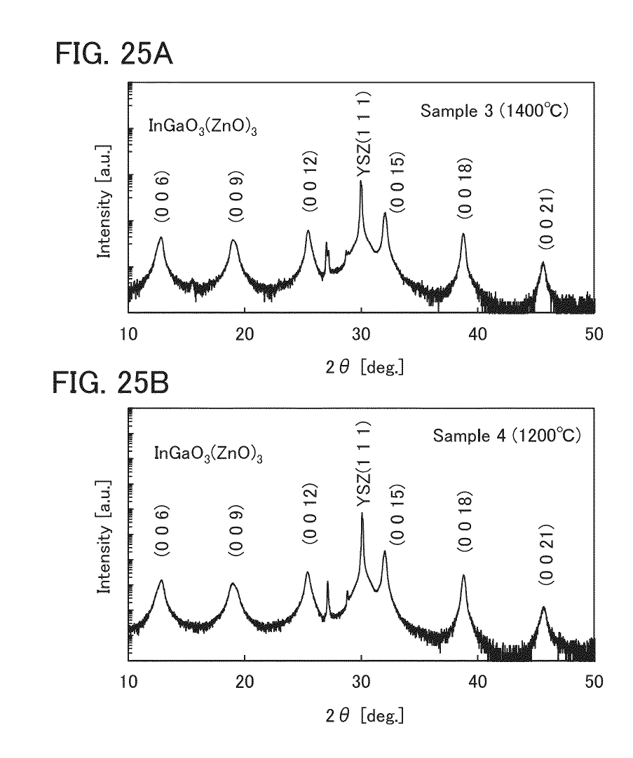

FIGS. 25A and 25B respectively show XRD spectra of Sample 3 and Sample 4 measured by an out-of-plane method.

From FIGS. 25A and 25B, each peak of Sample 3 and Sample 4 derived from the plane which is perpendicular to the c-axis of InGaO₃(ZnO)₃ is found. Accordingly, the above results suggest that c-axis of a crystal is strongly aligned with a normal direction of the formation surface in each of Sample 3 and Sample 4.

### [STEM Observation Results]

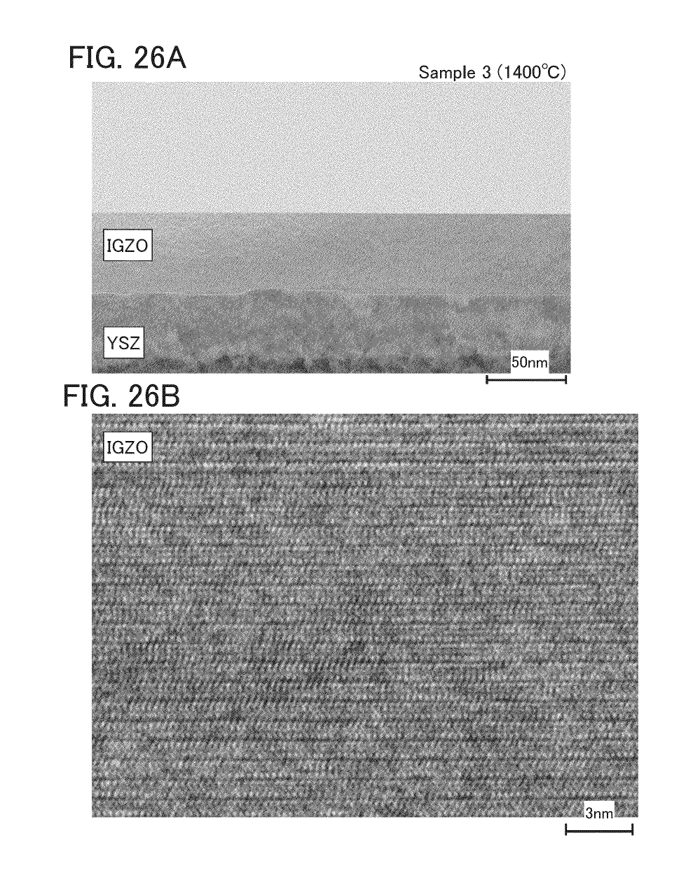

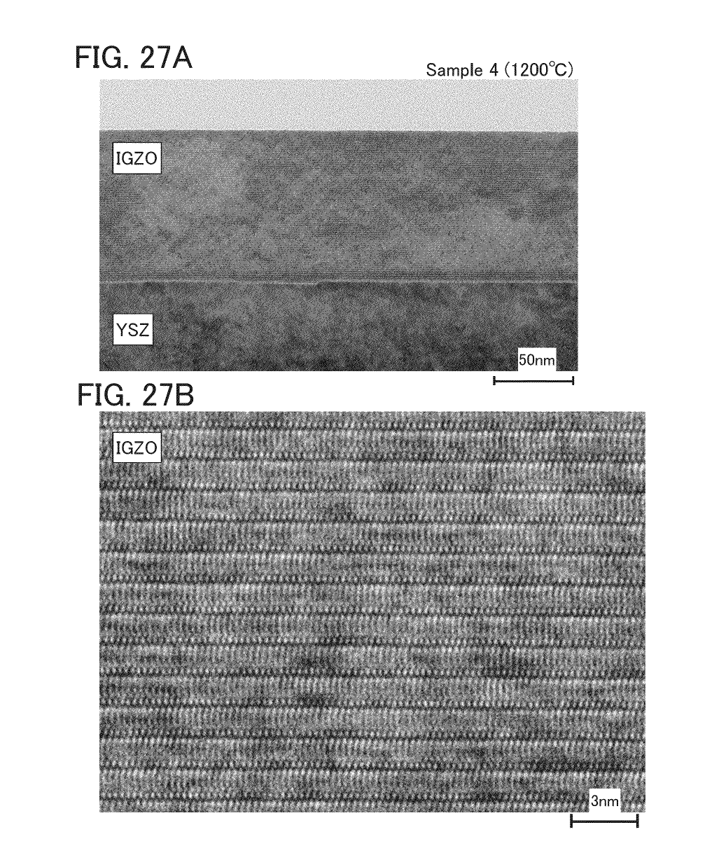

FIGS. 26A and 26B, and FIGS. 27A and 27B respectively show cross sectional images of Sample 3 and Sample 4 observed by STEM.

From FIG. 26A and FIG. 27A, it is found that a reduction in the thickness of the IGZO film is remarkable in Sample 3, which was subjected to heat treatment at 1400° C., compared to Sample 4, which was subjected to heat treatment at 1200° C. Thus, it is also found that a reduction in the thickness of the IGZO film can be effectively suppressed by setting the heating temperature to 1200° C.

From FIGS. 26A and 26B, layered stripes are observed in a direction parallel to the formation surface in Sample 3, and a state in which the whole In—Ga—Zn oxide film (IGZO film) is single-crystallized can be found.

From FIGS. 27A and 27B, in a manner similar to that of Sample 3, layered stripes are observed in a direction parallel to the formation surface, and a state in which the whole IGZO film is single-crystallized can be found in Sample 4.

Consequently, it is found that, by using an oxide film having crystal parts in which the c-axis are aligned with a direction parallel to the normal direction of the formation surface or a surface and having no crystal grain boundary between the crystal parts in the oxide film, the oxide film does not become polycrystalline even in the case where an oxide film is formed directly on the substrate without providing a ZnO film which serves as a buffer layer, and a favorable single crystal oxide film can be formed at a low temperature. In particular, it is found that sublimation of part of the oxide film can be effectively suppressed by performing heat treatment at a low temperature.

This application is based on Japanese Patent Application serial no. 2013-176003 filed with Japan Patent Office on Aug. 27, 2013, the entire contents of which are hereby incorporated by reference.

What is claimed is:

1. A method for forming a crystalline oxide film, comprising the steps of:
forming an oxide film comprising crystal parts over a formation surface; and
performing heat treatment at a temperature higher than or equal to 800° C. and lower than or equal to 1400° C., thereby performing a crystallization of the oxide film,
wherein the crystal parts have c-axis aligned with a direction parallel to a normal direction of the formation surface or a normal direction of a surface of the oxide film, and the oxide film does not have a crystal grain boundary between the crystal parts.

2. A method for manufacturing a semiconductor device, comprising the steps of:
forming an oxide film comprising crystal parts over a formation surface; and
performing heat treatment at a temperature higher than or equal to 800° C. and lower than or equal to 1400° C., thereby performing a crystallization of the oxide film,
forming a pair of electrodes in contact with the oxide film;
forming a gate insulating layer covering the oxide film; and
forming a gate electrode over the oxide film with the gate insulating layer therebetween,
wherein the crystal parts have c-axis aligned with a direction parallel to a normal direction of the formation surface or a normal direction of a surface of the oxide film, and the oxide film does not have a crystal grain boundary between the crystal parts.

3. The method for forming a crystalline oxide film according to claim 1,
wherein the crystallization is a single-crystallization.

4. The method for manufacturing a semiconductor device according to claim 2,
wherein the crystallization is a single-crystallization.

5. The method for forming a crystalline oxide film according to claim 1,
wherein the temperature is higher than or equal to 800° C. and lower than or equal to 1200° C.

6. The method for manufacturing a semiconductor device according to claim 2,
wherein the temperature is higher than or equal to 800° C. and lower than or equal to 1200° C.

7. The method for forming a crystalline oxide film according to claim 1,
wherein the oxide film is covered with a protective substrate or a protective film during the heat treatment.

8. The method for manufacturing a semiconductor device according to claim 2,
wherein the oxide film is covered with a protective substrate or a protective film during the heat treatment.

9. The method for forming a crystalline oxide film according to claim 1,
further comprising the step of forming a buffer layer on the formation surface prior to forming the oxide film.

10. The method for manufacturing a semiconductor device according to claim 2,
further comprising the step of forming a buffer layer on the formation surface prior to forming the oxide film.

11. The method for forming a crystalline oxide film according to claim 1,
further comprising the step of forming a buffer layer having an amorphous structure on the formation surface prior to forming the oxide film.

12. The method for manufacturing a semiconductor device according to claim 2,
further comprising the step of forming a buffer layer having an amorphous structure on the formation surface prior to forming the oxide film.

13. The method for forming a crystalline oxide film according to claim 1,
further comprising the step of forming a buffer layer on the formation surface by sputtering prior to forming the oxide film.

14. The method for manufacturing a semiconductor device according to claim 2,
further comprising the step of forming a buffer layer on the formation surface by sputtering prior to forming the oxide film.

15. The method for forming a crystalline oxide film according to claim 1,
further comprising the step of forming a zinc oxide layer on the formation surface by sputtering prior to forming the oxide film.

16. The method for manufacturing a semiconductor device according to claim 2,
further comprising the step of forming a zinc oxide layer on the formation surface by sputtering prior to forming the oxide film.

17. The method for forming a crystalline oxide film according to claim 1,
further comprising the step of forming a zinc oxide layer on the formation surface by sputtering at room temperature prior to forming the oxide film.

18. The method for manufacturing a semiconductor device according to claim 2,
further comprising the step of forming a zinc oxide layer on the formation surface by sputtering at room temperature prior to forming the oxide film.

19. The method for forming a crystalline oxide film according to claim 1,
wherein the heat treatment is performed under an atmosphere containing oxygen.

20. The method for manufacturing a semiconductor device according to claim 2,
wherein the heat treatment is performed under an atmosphere containing oxygen.
